(19) United States
(12) Patent Application Publication
(10) Pub. No.: US 2012/0160312 A1
(43) Pub. Date: Jun. 28, 2012

(54) SOLAR CELL

(75) Inventors: Yasuhiko ARAKAWA, Tokyo (JP); Tomohiro Nozawa, Osaka-shi (JP); Makoto Izumi, Osaka-shi (JP)

(73) Assignees: SHARP KABUSHIKI KAISHA, Osaka-shi (JP); The University of Tokyo, Tokyo (JP)

(21) Appl. No.: 13/335,505

(22) Filed: Dec. 22, 2011

(30) Foreign Application Priority Data
Dec. 22, 2010 (JP) 2010-286397
Mar. 15, 2011 (JP) 2011-056951

(51) Int. Cl. H01L 31/072

(52) U.S. Cl. 136/255

(57) ABSTRACT

A solar cell of the present invention comprises a p-type semiconductor layer, an n-type semiconductor layer and a superlattice semiconductor layer sandwiched between the p-type semiconductor layer and the n-type semiconductor layer, wherein the superlattice semiconductor layer has a superlattice structure in which barrier layers and quantum layers are stacked alternately and repeatedly, and has two or more intermediate energy levels where electrons optically excited from a valence band of the quantum layers or the barrier layers stay for a constant time, the intermediate energy levels being located between a top of the valence band of the barrier layers and a bottom of a conduction band of the barrier layers, and can achieve a high incident photon-to-current conversion efficiency.

### CROSS-REFERENCE TO RELATED APPLICATION

This application is related to Japanese Patent Application Nos. 2010-286397 filed on Dec. 22, 2010 and 2011-056951 filed on Mar. 15, 2011, whose priorities are claimed under 35 USC §119, and the disclosures of which are incorporated by reference in its entirety.

### BACKGROUND OF THE INVENTION

1. Field of the Invention

The present invention relates to a solar cell having a superlattice structure.

2. Description of the Related Art

In recent years, an attention is paid to photovoltaic elements as clean energy sources that do not emit CO₂, and thus they are being widely used. In such photovoltaic elements, currently the most popular photovoltaic elements are unijunction solar cells using silicon. However, energy conversion efficiency is approaching a theoretical limit of Shockle-Quisser (hereinafter referred to as SQ theoretical limit). For this reason, third-generation solar cells that exceed the SQ theoretical limit are being developed.

As such third-generation solar cells, the proposal is intermediate-band solar cells in which an intermediate band or a localized level (they are occasionally called as miniband in view of a quantum structure) is formed in a forbidden band. In the intermediate-band solar cells, electronic excitation from a valance band to an intermediate band and electronic excitation from the intermediate band to a conduction band are enabled by forming an intermediate band in a forbidden band of a semiconductor as a matrix. As a result, light of a smaller energy than a bandgap of the semiconductor as the matrix can be photoelectrically converted. For this reason, the intermediate-band solar cells are expected to have high energy conversion efficiency.

For example, in a model of the intermediate-band solar cells, it is reported that non-condensing energy conversion efficiency is about 46% (see Applied Physics Letters, Vol. 92, page 066101, 2008).

An intermediate-band solar cell, that has a tunnel barrier and a plurality of quantum dots embedded into an inorganic matrix, and an intermediate-band solar cell that has quantum dots embedded in an energy enclosing barrier are known (see National Publication of Japanese Translation of PCT Application Nos. 2009-520357 and 2010-509772).

In order to explain a phenomenon of an intermediate-band solar cell manufactured by InGaAs, Applied Physics Letters, Vol. 96, page 013501, 2010 describes a model of an intermediate-band solar cell utilizing a plurality of intermediate bands.

Journal of Applied Physics, Vol. 94, page 6150, 2003 describes that a number of the intermediate bands is set to be infinite so that efficiency of conversion from sunlight into electricity becomes a value that is close to a physical limit, and thus an intermediate-band solar cell is effective.

However, the Journal of Applied Physics, Vol. 94, page 6150, 2003 describes just the theoretical conversion efficiency when the solar cell receive full concentration, but does not describe concrete configuration example and method that realize the intermediate-band solar cell. In these configurations of the intermediate-band solar cells, their energy conversion efficiencies are not necessarily enough. For this reason, solar cells having higher energy conversion efficiency are desired.

### SUMMARY OF THE INVENTION

In view of the above-described circumstances, the present invention has been achieved to provide a solar cell whose energy conversion efficiency is higher.

The present invention provides a solar cell comprising a p-type semiconductor layer, an n-type semiconductor layer and a superlattice semiconductor layer sandwiched between the p-type semiconductor layer and the n-type semiconductor layer, wherein the superlattice semiconductor layer has a superlattice structure in which barrier layers and quantum layers are stacked alternately and repeatedly, and has two or more intermediate energy levels where electrons optically excited from a valence band of the quantum layers or the barrier layers stay for a constant time, the intermediate energy levels being located between a top of the valence band of the barrier layers and a bottom of a conduction band of the barrier layers.

According to the present invention, the superlattice semiconductor layer is sandwiched between the p-type semiconductor layer and the n-type semiconductor layer, and has a superlattice structure where the barrier layers and the quantum layers are stacked alternately and repeatedly. As a result, the superlattice semiconductor layer can be provided with intermediate energy levels, that are composed of quantum levels on a conduction band side of the quantum layers, between the top of the valence band of the barrier layers and the bottom of the conduction band of the barrier layers. At the intermediate energy levels, electrons optically excited from the valence band of the quantum layers or the valence band of the barrier layers can stay for a constant time. Particularly when the adjacent quantum layers are close to each other and miniband is formed due to electronic coupling of wave functions, a time for which the electrons, that are optically excited so as to move in the miniband, stay at the intermediate energy levels becomes longer. As a result, the electrons of the valence band of the barrier layers can be excited to the intermediate energy level by incident light, and the electrons at the intermediate energy levels can be excited to the conduction band of the barrier layers by the incident light. Such excitation of the electrons enables the electrons in the valence band of the barrier layers to be excited to the conduction band of the barrier layers via the intermediate energy level due to the incident light with a long wavelength that disables the electrons in the valence band of the barrier layers to be excited directly to the conduction band of the barrier layers.

Such optical excitation via the intermediate energy level enables the electrons to be generated in the conduction band of the barrier layer and holes to be generated in the valence band of the barrier layer and them to be optically converted. As a result, a photovoltaic power can be generated. Since such photoelectric conversion can utilize incident light with a longer wavelength, incident photon-to-current conversion efficiency can be heightened. Further, the superlattice semiconductor layer has two or more intermediate energy levels. As a result, since the two or more intermediate energy levels can be utilized for the optical excitation via the intermediate energy levels, incident light in wider wavelength range can be utilized for the photoelectric conversion, and the incident photon-to-current conversion efficiency can be further heightened.

### BRIEF DESCRIPTION OF THE DRAWINGS

FIG. 1 is a schematically cross-sectional view illustrating a configuration of a solar cell according to one embodiment of the present invention;

FIG. 2 is a schematically cross-sectional view illustrating a configuration of the solar cell according to one embodiment of the present invention;

FIG. 3 is a band diagram of a superlattice semiconductor layer, which has four intermediate energy levels and is included in the solar cell according to one embodiment of the present invention, and is an explanatory diagram describing a positional relationship of six levels;

FIG. 4 is a band diagram of the superlattice semiconductor layer, which has the four intermediate energy levels and is included in the solar cell according to one embodiment of the present invention, and is an explanatory diagram describing a relationship between a carrier generation rate “G” and an emission recombination “R”;

FIG. 5 is a band diagram of a superlattice semiconductor layer, which has one intermediate energy level and is included in a solar cell of a comparative example, and is an explanatory diagram describing a positional relationship between three levels;

FIG. 6 is a band diagram of the superlattice semiconductor layer, which has one intermediate energy level and is included in the solar cell of the comparative example, and is an explanatory diagram describing a relationship between the carrier generation rate “G” and the emission recombination “R”;

FIG. 7 is a graph showing a relationship between a band gap E_{g} and maximum energy conversion efficiency in a case of non-condensing obtained by a simulation of an experiment 1 according to the present invention;

FIG. 8 is a graph showing a relationship between the band gap E_{g} and the maximum energy conversion efficiency in a case of condensing obtained by the simulation of the experiment 1;

FIG. 9 is a band diagram of a superlattice semiconductor layer, which has three intermediate energy levels and is included in the solar cell according to one embodiment of the present invention, and is an explanatory diagram describing a positional relationship of five levels;

FIG. 10 is a band diagram of the superlattice semiconductor layer, which has three intermediate energy levels and is included in the solar cell according to one embodiment of the present invention, and is an explanatory diagram describing a relationship between the carrier generation rate “G” and the emission recombination “R”;

FIG. 11 is a graph showing a relationship between the band gap E_{g} and the maximum energy conversion efficiency in a case of non-condensing obtained by a simulation of an experiment 2 according to the present invention;

FIG. 12 is a graph showing a relationship between the band gap E_{g} and the maximum energy conversion efficiency in a case of condensing obtained by the simulation of the experiment 2;

FIG. 13 is a band diagram of a superlattice semiconductor layer, which has two intermediate energy levels and is included in the solar cell according to one embodiment of the present invention, and is an explanatory diagram describing a positional relationship between four levels;

FIG. 14 is a band diagram of the superlattice semiconductor layer, which has two intermediate energy levels and is included in the solar cell according to one embodiment of the present invention, and is an explanatory diagram describing a relationship between the carrier generation rate “G” and the emission recombination “R”;

FIG. 15 is a graph showing a relationship between the band gap E_{g} and the maximum energy conversion efficiency in a case of non-condensing obtained by a simulation of an experiment 3 according to the present invention;

FIG. 16 is a graph showing a relationship between the band gap E_{g} and the maximum energy conversion efficiency in the case of the condensing obtained by the simulation of the experiment 3;

FIG. 17 is a diagram showing a result of calculating a band structure of a superlattice semiconductor layer of a 4-levels intermediate-band solar cell obtained by a simulation of an experiment 4-1 according to the present invention;

FIG. 18 is a graph showing a relationship between a voltage and an electric current when no concentration light is irradiated to a 4-levels intermediate-band solar cell obtained by the simulation of the experiment 4-1;

FIG. 19 is a graph showing a relationship between a voltage and an electric current when 1000 suns concentration light is irradiated to the 4-levels intermediate-band solar cell obtained by the simulation of the experiment 4-1;

FIG. 20 is a diagram showing a result of calculating a band structure of a superlattice semiconductor layer of a 5-levels intermediate-band solar cell obtained by a simulation of an experiment 4-2 according to the present invention;

FIG. 21 is a graph showing a relationship between a voltage and an electric current when no concentration light is irradiated to the 5-levels intermediate-band solar cell obtained by the simulation of the experiment 4-2;

FIG. 22 is a graph showing a relationship between a voltage and an electric current when 1000 suns concentration light is irradiated to the 5-levels intermediate-band solar cell obtained by the simulation of the experiment 4-2;

FIG. 23 is a diagram showing a result of calculating a band structure of a superlattice semiconductor layer of a 6-levels intermediate-band solar cell obtained by a simulation of an experiment 4-3 according to the present invention;

FIG. 24 is a graph showing a relationship between a voltage and an electric current when no concentration light is irradiated to a 6-levels intermediate-band solar cell obtained by a simulation of the experiment 4-3;

FIG. 25 is a graph showing a relationship between a voltage and an electric current when 1000 suns concentration light is irradiated to the 6-levels intermediate-band solar cell obtained by the simulation of the experiment 4-3;

FIG. 26 is a diagram showing a result of calculating a band structure of a superlattice semiconductor layer of the 4-levels intermediate-band solar cell obtained by a simulation of an experiment 5-1 according to the present invention;

FIG. 27 is a graph showing a relationship between a voltage and an electric current when no concentration light is irradiated to the 4-levels intermediate-band solar cell obtained by the simulation of the experiment 5-1;

FIG. 28 is a graph showing a relationship between a voltage and an electric current when 1000 suns concentration light is irradiated to the 4-levels intermediate-band solar cell obtained by the simulation of the experiment 5-1;

FIG. 29 is a diagram showing a result of calculating a band structure of a superlattice semiconductor layer of the 5-levels intermediate-band solar cell obtained by a simulation of an experiment 5-2 according to the present invention;

FIG. 30 is a graph showing a relationship between a voltage and an electric current when no concentration light is irradiated to the 5-levels intermediate-band solar cell obtained by the simulation of the experiment 5-2;

FIG. 31 is a graph showing a relationship between a voltage and an electric current when 1000 suns concentration light is irradiated to the 5-levels intermediate-band solar cell obtained by the simulation of the experiment 5-2;

FIG. 32 is a diagram showing a result of calculating a band structure of a superlattice semiconductor layer of a 6-levels intermediate-band solar cell obtained by a simulation of an experiment 5-3 according to the present invention;

FIG. 33 is a graph showing a relationship between a voltage and an electric current when no concentration light is irradiated to the 6-levels intermediate-band solar cell obtained by the simulation of the experiment 5-3;

FIG. 34 is a graph showing a relationship between a voltage and an electric current when 1000 suns concentration light is irradiated to the 6-levels intermediate-band solar cell obtained by the simulation of the experiment 5-3;

FIG. 35 is a diagram showing a result of calculating a band structure of a superlattice semiconductor layer of the 4-levels intermediate-band solar cell obtained by a simulation of an experiment 6 according to the present invention;

FIG. 36 is a diagram showing a result of calculating a band structure of the superlattice semiconductor layer of the 4-levels intermediate-band solar cell obtained by the simulation of the experiment 6; and

FIG. 37 is a diagram showing a result of calculating a band structure of a superlattice semiconductor layer of the 6-levels intermediate-band solar cell obtained by a simulation of an experiment 7 according to the present invention.

### DETAILED DESCRIPTION OF THE PREFERRED EMBODIMENTS

A solar cell of the present invention comprises a p-type semiconductor layer, an n-type semiconductor layer and a superlattice semiconductor layer sandwiched between the p-type semiconductor layer and the n-type semiconductor layer, wherein the superlattice semiconductor layer has a superlattice structure in which barrier layers and quantum layers are stacked alternately and repeatedly, and has two or more intermediate energy levels where electrons optically excited from a valence band of the quantum layers or the barrier layers stay for a constant time, the intermediate energy levels being located between a top of the valence band of the barrier layers and a bottom of a conduction band of the barrier layers.

In the present invention, the p-type semiconductor layer, the n-type semiconductor layer and the superlattice semiconductor layer compose a photoelectric conversion layer.

In the present invention, the superlattice structure is such that the barrier layers and the quantum layers are stacked alternately and repeatedly, and is such that quantum levels of the two quantum layers adjacent to each other via the barrier layer are interacted.

In the present invention, the quantum layers are made of a semiconductor material having a band gap narrower than that of a semiconductor material of which the barrier layers are made, and has discrete energy levels (quantum levels) due to a quantum effect.

In the present invention, the barrier layers are made of a semiconductor material having a band gap wider than that of a semiconductor material of which the quantum layers are made, and forms a potential barrier around the quantum layers.

In the solar cell of the present invention, it is preferable that each of the intermediate energy levels is composed of quantum levels on the conduction band side of the quantum layers, and an effective bandgap between the quantum level at the top on a valence band side of the quantum layers and the bottom of the conduction band of the barrier layers is 1.0 eV or more to 3.8 eV or less.

Such a configuration has two or more intermediate energy levels capable of being utilized for optical excitation excluding a plurality of dense quantum levels for forming the valence bands capable of being substantially regarded as one band, and the effective bandgap between the quantum level at the top on the valence band side of the quantum layers and the bottom of the conduction band of the barrier layers is 1.0 eV or more to 3.8 eV or less. For this reason, incident photon-to-current conversion efficiency of this solar cell can be made to be higher than that of an intermediate-band solar cell having one intermediate energy level usable for optical excitation.

In the solar cell of the present invention, the quantum layers are preferably quantum dot layers, each of which is composed of quantum dots.

In such a configuration, an electronic energy can be confined within a quantum dot, and the quantum dot can be provided with quantum levels. Utilization of the quantum levels can form the intermediate energy levels, and the electrons of the valence band of the barrier layers can be optically excited to the conduction band of the barrier layers via the intermediate energy levels.

In the solar cell of the present invention, the quantum layers or the barrier layers are preferably made of a group III-V compound semiconductor, a group II-VI compound semiconductor or a chalcopyrite semiconductor.

According to such a configuration, minibands are easily formed on the superlattice semiconductor layer, and the intermediate energy levels are easily formed at an energy level suitable for photoelectric conversion. Further, the effective bandgap can be in a suitable range.

In the solar cell of the present invention, the quantum layers or the barrier layers are preferably made of a group III-V compound semiconductor including at least one element of Al, Ga and In, and at least one element of As, Sb and P.

According to such a configuration, minibands are easily formed on the superlattice semiconductor layer, and the intermediate energy levels are easily formed at an energy level suitable for photoelectric conversion. Further, the effective bandgap can be set within a suitable range.

In the solar cell of the present invention, it is preferable that the quantum layers are made of InSbₓAs₁₋ₓ (0≦x≦1), and the barrier layers are made of AlSb_{y}As_{1-y} (0≦y≦1).

According to such a configuration, a valence band offset as a difference between the top of the valence band of the barrier layers and a top of a valence band of a material (bulk) forming the quantum layers can be small, and the effective bandgap can be set within a suitable range. Further, the valence band offset can be set to be 0.

In the solar cell of the present invention, the valence band offset as the difference between the top of the valence band of the barrier layers and the top of the valence band of the material forming the quantum layers is preferably 0.0 eV or more to 0.28 eV or less.

According to such a configuration, a miniband is easily formed from a electronically combination of the quantum levels on the valence band side of the quantum layers, and electron holes generated at the quantum levels on the valence band side of the quantum layers easily transfers to the p-type semiconductor layer, and thus incident photon-to-current conversion efficiency can be heightened.

In the solar cell of the present invention, the quantum layers preferably have the valence band that can be substantially regarded as one band, the valence band being composed of a plurality of quantum levels on the valence band side of the quantum layers.

According to such a configuration, the electron holes generated at the quantum levels on the valence band side of the quantum layers easily flow to the p-type semiconductor layer. For this reason, these electron holes can be utilized for photoelectric conversion, and the incident photon-to-current conversion efficiency can be heightened.

In the solar cell of the present invention, it is preferable that the valence band offset as the difference between the top of the valence band in the barrier layers and the top of the valence band of the material forming the quantum layers is substantially 0 eV.

According to such a configuration, the electron holes generated at the quantum levels on the valence band side of the quantum layers easily transfer to the p-type semiconductor layer, and the incident photon-to-current conversion efficiency can be heightened.

In the solar cell of the present invention, the intermediate energy levels are preferably intermediate bands, each of which comprises electronically combining wave functions of the quantum levels of the quantum layers composing the superlattice structure.

According to such a configuration, the electrons optically excited from the valence band of the barrier layers or the valence band of the quantum layers to the intermediate energy levels can transfer in the intermediate bands, thereby heightening a probability that the electrons are excited to the conduction band of the barrier layers. For this reason, the incident photon-to-current conversion efficiency can be heightened.

In the solar cell of the present invention, it is preferable that the two intermediate energy levels are present, and the effective bandgap is 1.0 eV or more to 3.5 eV or less.

According to such a configuration, the incident photon-to-current conversion efficiency can be made to be higher than that of the solar cell having one intermediate energy level.

In the solar cell of the present invention, it is preferable that the three intermediate energy levels are present, and the effective bandgap is 1.1 eV or more to 3.8 eV or less.

According to such a configuration, the incident photon-to-current conversion efficiency can be made to be higher than that of the solar cell having one intermediate energy level.

In the solar cell of the present invention, it is preferable that the four intermediate energy levels are present, and the effective bandgap is 1.3 eV or more to 3.8 eV or less.

According to such a configuration, the incident photon-to-current conversion efficiency can be made to be higher than that of the solar cell having one intermediate energy level.

In the solar cell of the present invention, each of the barrier layers preferably has a thickness of 3 nm or less.

According to such a configuration, minibands are easily formed from electronically combination of the quantum levels on the conduction band side of the quantum layers, and the intermediate energy levels can be the intermediate bands.

An embodiment of the present invention will be described below with reference to the drawings. Configurations shown in the drawings and the following description are examples, and the scope of the present invention is not limited to the drawings and the following description.

### Configuration of the Solar Cell

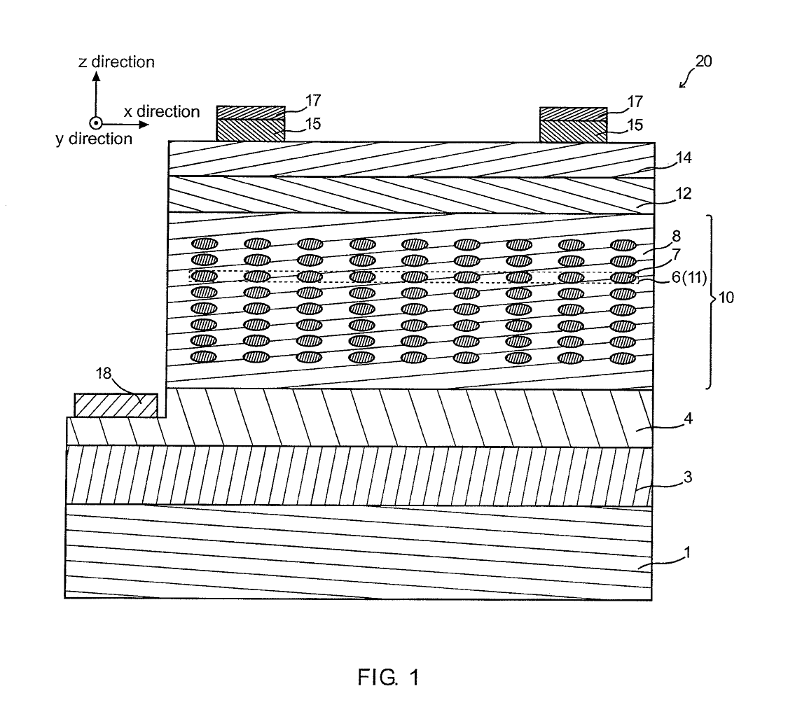

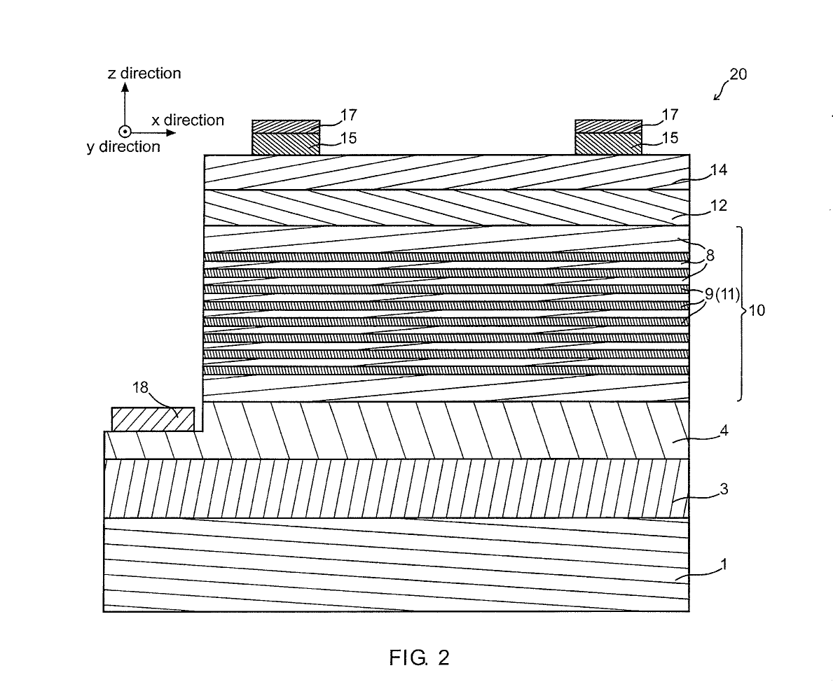

FIGS. 1 and 2 are schematically cross-sectional views illustrating configurations of the solar cell according to one embodiment of the present invention.

A solar cell 20 according to the embodiment includes a p-type semiconductor layer 4, an n-type semiconductor layer 12, and a superlattice semiconductor layer 10 sandwiched between the p-type semiconductor layer 4 and the n-type semiconductor layer 12. The superlattice semiconductor layer 10 has the superlattice structure in which barrier layers 8 and quantum layers 11 are stacked alternately and repeatedly, and has two or more intermediate energy levels at which the electrons optically excited from the valence band of the quantum layers 11 or the barrier layers 8 stay for a constant time, the intermediate energy levels being located between the top of the valence band of the barrier layers 8 and the bottom of the conduction band of the barrier layers 8. The intermediate energy level is formed by the quantum level on the conduction band side of the quantum layer 11. The effective bandgap between quantum level at the top on the valence band of the quantum layers 11 and the bottom of the conduction band of the barrier layers 8 is 1.0 eV or more to 3.8 eV or less.

The solar cell 20 according to the embodiment may have a substrate 1, a buffer layer 3, a window layer 14, a contact layer 15, and an n-type electrode 17 or a p-type electrode 18.

The solar cell according to the embodiment will be described below.

### 1. P-Type Semiconductor Layer and N-Type Semiconductor Layer

The p-type semiconductor layer 4 is made of a semiconductor including p-type impurities. The p-type semiconductor layer 4, the superlattice semiconductor layer 10 and the n-type semiconductor layer 12 can compose pin junction or pn junction (including pn⁻n junction, pp⁻n junction, p⁺pn junction, and pnn⁺ junction).

The n-type semiconductor layer 12 is made of a semiconductor including n-type impurities. The n-type semiconductor layer 12, the superlattice semiconductor layer 10 and the p-type semiconductor layer 4 can compose pin junction or pn junction (including pn⁻n junction, pp⁻n junction, p⁺pn junction, and pnn⁺ junction).

When the pin junction or pn junction receive light, electrons and holes are generated on the superlattice semiconductor layer by incident light and are outputted as photovoltaic power. As a result, the solar cell 20 can output electricity.

The p-type semiconductor layer 4 and the n-type semiconductor layer 12 sandwich the superlattice semiconductor layer 10. In these configurations, for example, as shown in FIGS. 1 and 2, the p-type semiconductor layer 4, the superlattice semiconductor layer 10 and the n-type semiconductor layer 12 may be formed in this order on the substrate 1. The n-type semiconductor layer 12, the superlattice semiconductor layer 10 and the p-type semiconductor layer 4 may be formed in this order on the substrate 1. The superlattice semiconductor layer 10 and the n-type semiconductor layer 12 may be formed in this order on a p-type semiconductor substrate. The superlattice semiconductor layer 10 and the p-type semiconductor layer 4 may be formed in this order on an n-type semiconductor substrate. Further, the buffer layer 3 may be provided between the substrate 1 and the p-type semiconductor layer 4 or the n-type semiconductor layer 12. Further, the window layer 14 may be formed on these structures.

The p-type semiconductor layer 4 and the n-type semiconductor layer 12 can be formed by, for example, an MOCVD method.

The p-type semiconductor layer 4 can be electrically connected to the p-type electrode 18, and the n-type semiconductor layer 12 can be electrically connected to the n-type electrode 17. As a result, a photovoltaic power generated between the p-type semiconductor layer 4 and the n-type semiconductor layer 12 can be output to an external circuit via the p-type electrode 18 and the n-type electrode 17. Further, the contact layer 15 may be provided between the p-type semiconductor layer 4 and the p-type electrode 18 or between the n-type semiconductor layer 17 and the n-type electrode 17.

For example, when the p-type semiconductor layer (base layer) 4 made of AlSb_{0.5}As_{0.5} is formed on the p-type semiconductor substrate 1 made of GaAs, as shown in FIGS. 1 and 2, the p-type electrode 18 is formed on an exposed surface of interface between the superlattice semiconductor layer 10 and the p-type semiconductor layer (the base layer) 4 or on an exposed surface of the base layer (the p-type semiconductor layer) 4. For example, the exposed surface is formed by etching until the interface or the p-type semiconductor layer 4 is exposed. As a result, GaAs is used for the p-type semiconductor substrate 1 and AlSb_{0.5}As_{0.5} is used for the p-type semiconductor layer (the base layer) 4, so that the solar cell 20 can be formed.

Further, for example, a GaSb substrate whose lattice constants are close to each other can be used.

### 2. Superlattice Semiconductor Layer

The superlattice semiconductor layer 10 is sandwiched between the p-type semiconductor layer 4 and the n-type semiconductor layer 12, and has the superlattice structure in which the barrier layers 8 and the quantum layers 11 are stacked alternately and repeatedly. The quantum layer 11 is made of a semiconductor material having a band gap narrower than that of the semiconductor material composing the barrier layer 8, and has a plurality of quantum levels on the conduction band side and the valence band side due to a quantum effect. The quantum layer 11 may be a quantum dot layer 6 as shown in FIG. 1, and may be a quantum well layer 9 as shown in FIG. 2.

The barrier layer 8 is made of a semiconductor material having a band gap wider than that of the semiconductor material composing the quantum layer 11, and forms a potential barrier around the quantum layer 11. As a result, the superlattice semiconductor layer 10 can be provided with the intermediate energy level formed by the quantum levels of the quantum layers 11 between the top of the valence band of the barrier layers 8 and the bottom of the conduction band of the barrier layers 8. At the intermediate energy level, electrons optically excited from the valence band of the quantum layers 11 or the valence band of the barrier layers 8 stay for a constant time. As a result, the electrons in the valence band of the barrier layer 8 can be excited to the intermediate energy level due to incident light, and the electrons at the intermediate energy level can be excited to the conduction band of the barrier layers 8 due to incident light. As a result, the excitation of the electrons enables the electrons in the valence band of the barrier layers 8 to be excited to the conduction band of the barrier layers 8 via the intermediate energy level due to incident light with a long wavelength that cannot directly excite the electrons of the valence band of the barrier layers 8 to the conduction band of the barrier layers 8.

Such optical excitation generates electrons in the conduction band of the barrier layer 8, and generates holes in the valence band of the barrier layer 8. As a result, photoelectric conversion can be carried out, and a photovoltaic power can be generated. Since the photoelectric conversion can utilize incident light with a longer wavelength, the incident photon-to-current conversion efficiency can be heightened.

The semiconductor material of which the barrier layer 8 or the quantum layer 11 composing the superlattice semiconductor layer 10 is made may be an i-type semiconductor. When an electromotive force is generated by light reception, the barrier layer 8 or the quantum layer 11 may be semiconductor layer including p-type impurities or n-type impurities. Further, the semiconductor material of which the barrier layer 8 or the quantum layer 11 composing the superlattice semiconductor layer 10 is made is group III-V compound semiconductors including at least one element of Al, Ga and In, and at least one element of As, Sb and P. For example, AlSb, InAsₓSb₁₋ₓ (here, x is element ratio, 0≦x≦1. Much the same is true on the following description unless particular reference is made), AlSbₓAs₁₋ₓ, AlAs, GaAs, and InₓGa₁₋ₓAs can be used. Further, for example, a group IV semiconductor, a group III and V compound semiconductor, a group II and VI compound semiconductor in a periodic table, or a mixed crystal material may be used. Further, a chalcopyrite-type semiconductor may be used, or the other semiconductors may be used. For example, the quantum layer 11 is made of InSbₓAs₁₋ₓ (0≦x≦1), and the barrier layer is made of AlSb_{y}As_{1-y} (0≦y≦1). For example, GaNAs is used for the material of the barrier layer 8, and InAs is used for the material of the quantum layer 11. GaP is used for the material of the barrier layer 8, and InAs is used for the material of the quantum layer 11. GaN is used for the material of the barrier layer 8, and GaₓIn₁₋ₓN is used for the material of the quantum layer 11. GaAs is used for the material of the barrier layer 8, and GaSb is used for the material of the quantum layer 11. AlAs is used for the material of the barrier layer 8, and InAs is used for the material of the quantum layer 11. CuGaS₂ is used for the material of the barrier layer 8, and CuInSe₂ is used for the material of the quantum layer 11.

The barrier layer 8 may be made of AlSb, and the quantum layer 11 may be made of InAs₁₋ₓSbₓ (0≦x≦1). The barrier layer 8 may be made of AlSb_{y}As_{1-y} (0≦y≦1), and the quantum layer 11 may be made of InAs. The barrier layer 8 may be made of AlAs, and the quantum layer 11 may be made of InAs. Further, the barrier layer 8 may be made of GaN, and the quantum layer 11 may be made of In_{z}Ga_{1-z}N (0≦z≦1).

For example, the quantum layer 11 may be made of InAsₓSb₁₋ₓ, and the barrier layer 8 may be made of AlSb. In this case, it is preferable that the element ratio x is suitably changed because the lattice constant can be adjusted to AlSb, a valence band energy offset (a valence band energy difference between the quantum dot layer and the barrier layer) can be set to be zero.

The quantum layer 11 may be InAs, and the barrier layer 8 may be made of AlSb_{y}As_{1-y}.

When the quantum layers 11 included in the superlattice semiconductor layer 10 is the quantum well layers 9 as shown in FIG. 2, the superlattice semiconductor layer 10 can be formed by alternately laminating the barrier layers 8 and the quantum well layers 9. At this time, a thickness of the quantum well layer 9 is, for example, 1 nm or more to 100 nm or less, preferably 1 nm or more to 50 nm or less, and more preferably 1 nm or more to 20 nm or less. As a result, the quantum well layer 9 can be provided with a plurality of quantum levels on a valence band side and a conduction band side due to the quantum effect. Further, a thickness of the barrier layer 8 can be set to, for example, 1 nm or more to 10 nm or less, preferably 1 nm or more to 5 nm or less, and more preferably 1 nm or more to 3 nm or less. As a result, wave functions of the quantum levels in the adjacent two quantum well layers 9 can be electronically coupled, and a resonance tunnel effect between these quantum levels can be produced.

The thicknesses of the quantum well layers 9 included in the superlattice semiconductor layer 10 may be equal to or different from each other. The thicknesses of the barrier layers 8 included in the superlattice semiconductor layer 10 may be equal to or different from each other.

The quantum well layers 9 have the valence band that is composed of a plurality of quantum levels on the valence band side and can be substantially regarded as one band. “The valence band that can be substantially regarded as one band” means a valence band where a plurality of quantum levels can be substantially regarded as one level because the plurality of quantum levels on the valence band side of the quantum well layer 9 is formed densely. It is more preferable that an energy difference between the adjacent quantum levels is a room-temperature energy (about 25 meV) or less because carriers can freely move between the quantum levels at room temperature. “The valence band that can be substantially regarded as one band” is formed in cases where the valence band offset is zero or not zero.

In this case, an energy width between the top of the valence band, substantially regarded as one band, of the quantum well layers 9 and the bottom of the conduction band of the barrier layers 8 is called as an effective bandgap.

In the superlattice semiconductor layer 10, the valence band offset as the difference between the top of the valence band of the barrier layers 8 and the top of the valence band of the material (bulk) forming the quantum well layers 9 may be 0.0 eV or more to 0.28 eV or less. Further, more preferably the offset is practically 0 eV. As a result, the wave functions of the quantum levels on the valence band side of the quantum well layers 9 are easily combined, so that minibands can be formed. As a result, the holes formed at the quantum levels on the valence band side of the quantum well layers 9 by optical excitation can easily move, and thus the holes can be efficiently used for photoelectric conversion, thereby heightening the incident photon-to-current conversion efficiency.

The valence band offset may be 0, 0.04, 0.08, 0.1, 0.12, 0.15, 0.2, 0.24, 0.28, or 0.3 eV, or may be a range between any two of these numerical values.

The material of the quantum well layer 9, a mixed crystal ratio in the material of the quantum well layer 9, the thickness of the quantum well layer 9, the material of the barrier layer 8, a mixed crystal ratio in the material of the barrier layer 8, and a thickness of the barrier layer 8 are selected so that the following state are obtained. The two or more intermediate energy levels quantized in a direction z where the electrons optically excited stay for a constant time are formed between the top of the valence band of the barrier layers 8 and the bottom of the conduction band of the barrier layers 8. These intermediate energy levels exclude a plurality of dense quantum levels for forming the valence band that can be substantially regarded as one band. Further, the effective bandgap between the quantum level at the top on the valence band side of the quantum well layers 9 and the bottom of the conduction band of the barrier layers 8 is 1.0 eV or more to 3.8 eV or less.

When the quantum layers 11 included in the superlattice semiconductor layer 10 are composed of the quantum dot layer 6 made of the plurality of quantum dots 7 as shown in FIG. 1, the superlattice semiconductor layer 10 can be formed by alternately laminating the barrier layers 8 and the quantum dot layers 6.

The quantum dot layer 6 can be formed by a method that is called as Stranski-Krastanov (S-K) growth using a molecular beam epitaxy (MBE) method or an organic metal chemistry gaseous phase growth method (MOCVD), an electron lithography technique, or a droplet epitaxy method. The S-K growth method is a method utilizing an island structure with a nano size based on the S-K growth mechanism appearing at the time of forming a thin film. With the S-K growth method, when a component ratio of raw materials forming a thin film is changed, the mixed crystal ratio of the quantum dots can be adjusted, and when raw materials, a growth temperature, a pressure, and a deposition time are changed, the size of the quantum dots can be adjusted. The droplet epitaxy method can be used also for a case where the lattice constants of the material composing the barrier layer and the material composing the quantum dot layer are close to each other.

A particle size of the quantum dots 7 included in the quantum dot layer 6 can be expressed by a size x in an x direction parallel to a stacked surface, a size y in a y direction parallel to a stacked surface, and a thickness z in a z direction vertical to the stacked surface as shown in FIG. 1, and the particle size can be expressed by (x nm, y nm and z nm). The quantum dots 7 included in the respective quantum dot layers 6 can be regarded to have the substantially same size. For this reason, the quantum dots 7 of the respective quantum dot layers 6 can be regarded to have the substantially same quantum level, and the quantum level of the quantum dots 7 can be regarded to be the quantum level of the quantum dot layer 6 including the quantum dots 7.

The thickness z of the quantum dots 7 included in each quantum dot layer 6 can be set to, for example, 1 nm or more to 100 nm or less, preferably 1 nm or more to 50 nm or less, and more preferably 1 nm or more to 20 nm or less. As a result, the quantum dots 7 included in each quantum dot layer 6 can be provided with a plurality of quantum levels on the valence band side and the conduction band side due to the quantum effect. The thickness of the barrier layer 8 can be set to, for example, 1 nm or more to 10 nm or less, preferably 1 nm or more to 5 nm or less, and more preferably 1 nm or more to 3 nm or less. As a result, the wave functions of quantum levels of the quantum dots 7 included in the adjacent two quantum dot layers 6 can be electronically combined, thereby producing the resonance tunnel effect between the quantum levels.

The thicknesses z of the quantum dots 7 included in the different quantum dot layers 6 may be the same as or different from each other. Further, the thicknesses of the barrier layers 8 included in the superlattice semiconductor layer 10 may be the same as or different from each other.

The quantum dot layer 6 (the quantum dots 7) can be provided with the valence band that is composed of the plurality of quantum levels on the valence band side and can be substantially regarded as one band. “The valence band that can be substantially regarded as one band” means the valence band where the plurality of quantum levels can be substantially regarded as one level because the plurality of quantum levels on the valence band side of the quantum dot layer 6 (the quantum dots 7) is formed densely. “The valence band that can be substantially regarded as one band” is formed in cases where the valence band offset is zero and not zero.

In this case, the energy width between the top of the valence band, substantially regarded as one band, of the quantum dot layer 6 (the quantum dots 7) and the bottom of the conduction band of the barrier layer 8 is called as the effective bandgap.

The superlattice semiconductor layer 10 may have the valence band offset as the difference between the top of the valence band of the barrier layer 8 and the top of the valence band of the material (bulk) forming the quantum dot layer 6 (the quantum dots 7) that is 0.0 eV or more to 0.28 eV or less or substantially 0 eV. As a result, the wave functions of the quantum levels on the valance band side of the quantum dots 7 included in the respective quantum dot layers 6 are easily combined, and minibands can be formed. As a result, the holes formed at the quantum level on the valence band side of the quantum dots 7 by optical excitation can easily move, and the holes can be efficiently used for the photoelectric conversion, thereby further heightening the incident photon-to-current conversion efficiency.

The valence band offset may be 0, 0.04, 0.08, 0.1, 0.12, 0.15, 0.2, 0.24, 0.28, or 0.3 eV, or may be in a range between any two of these numerical values.

The material of the quantum dots 7, the mixed crystal ratio in the material of the quantum dots 7, the thickness z of the quantum dots 7, the material of the barrier layer 8, the mixed crystal ratio in the material of the barrier layer 8, and the thickness of the barrier layer 8 are selected so that the following state is obtained. The two or more intermediate energy levels where the electrons optically excited stay for a constant time are formed between the top of the valence band of the barrier layer 8 and the bottom of the conduction band of the barrier layer 8. These intermediate energy levels exclude a plurality of dense quantum levels for forming the valence band that can be substantially regarded as one band. The effective bandgap between the quantum level at the top on the valence band side of the quantum dot layer 6 and the bottom of the conduction band of the barrier layer 8 becomes 1.0 eV or more to 3.8 eV or less.

The intermediate energy level formed on the superlattice semiconductor layer 10 is formed by the quantum levels of the quantum layers 11. The intermediate energy level may be composed of the quantum levels on the conduction band side of the quantum layers 11. Further, the intermediate energy level may be miniband formed by the quantum levels of the respective quantum layers 11. In this case, the carrier motion at the intermediate energy level becomes easy, and the optical excitation from the valence band of the barrier layer 8 to the conduction band of the barrier layer 8 utilizing the intermediate energy level can be caused efficiently. As a result, the incident photon-to-current conversion efficiency can be further heightened.

The miniband means the intermediate band that is formed by combining the quantum levels of the quantum layers 11 in the superlattice structure by a resonance tunnel effect of the wave functions of the electrons of the adjacent quantum layers 11 which interact therebetween.

At the intermediate energy level formed in the superlattice semiconductor layer 10, the electrons optically excited from the valence band of the quantum layers 11 or the valence band of the barrier layer 8 stay for a constant time. As a result, the electrons optically excited can be allowed to stay at the intermediate energy level, and the electrons present at the intermediate energy level can be further optically excited to the conduction band of the barrier layer 8. As a result, the electrons can be optically excited from the valence band of the barrier layer 8 to the conduction band of the barrier layer 8 by utilizing the intermediate energy level.

When the miniband is formed, the electrons can move in the miniband, and thus a time for which the optically excited electrons stay becomes longer.

Whether the intermediate energy level, at which the optically excited electrons from the valence band of the quantum layers 11 or the valence band of the barrier layer 8 stay for a constant time, is present can be confirmed by measuring emission spectrum via, for example, PL (photoluminescence) measurement. For example, an Ar laser is used for an excitation light source, and a Ge photodetector is used for a detector, so that photoluminescence of the superlattice semiconductor layer 10 is measured with 11 K. An energy (a photon energy) corresponding to a luminescent band of the measured emission spectrum is obtained, so that a level where the intermediate energy level is formed can be confirmed. Further, the bandgap of the barrier layer 8 can be confirmed. An optical absorption spectrum is measured, so that the formation of the intermediate energy level may be confirmed.

Two or more intermediate energy levels are formed in the superlattice semiconductor layer 10. The number of the intermediate energy levels can be confirmed by the PL measurement and the optical absorption spectrum.

The superlattice semiconductor layer 10 can be provided with the two or more intermediate energy levels in a forbidden band of the barrier layer 8 (namely, between the conduction band and the valence band of the barrier layer 8). A position (energy level) where the intermediate energy level is formed is not uniquely determined. That is to say, the position (the energy level) may be determined according to a wavelength of the light that is to be photoelectrically converted by the solar cell. The position (the energy level) may be different between a space solar cell and a solar cell for ground use. For example, the superlattice semiconductor layer 10 may be provided with the two intermediate energy levels on the conduction band side of the quantum layers 11. Further, the number of the intermediate energy levels included in the superlattice semiconductor layer 10 may be three or four.

When the intermediate energy level is formed between the conduction band of the barrier layer 8 and the valence band of the barrier layer 8, the solar cell can be divided according to the total number of the energy levels at the bottom of the conduction band of the barrier layer 8 and the top of the valence band, substantially regarded as one band, of the quantum layers 11 and the intermediate energy level. For example, the solar cell whose superlattice semiconductor layer 10 has the two intermediate energy levels can be a 4-levels intermediate-band solar cell, and the solar cell whose superlattice semiconductor layer 10 has the three intermediate energy levels can be a 5-levels intermediate-band solar cell. The solar cell whose superlattice semiconductor layer 10 has the four intermediate energy levels can be a 6-levels intermediate-band solar cell.

For example, the energy level at the top of the valence band of the barrier layer 8, or the energy level at the top of the valence band of the quantum layers 11 substantially regarded as one band can be represented by Eᵥ, and the energy level at the bottom of the conduction band of the barrier layer 8 can be represented by E_{c}. Further, the intermediate energy level can be represented by Eᵢ, and for example, the intermediate energy level in the intermediate energy levels that is the closest to E_{c} can be represented by Eᵢ₁. The intermediate energy level that is the second closest to E_{c} can be expressed by Eᵢ₂, the third closest one can be represented by Eᵢ₃, and the fourth closest one can be expressed by Eᵢ₄.

An energy difference between E_{c} and Eᵢ can be represented by ΔE_{ci}, and a difference between two Eᵢ can be represented by ΔEᵢᵢ. An energy difference between Eᵥ and Eᵢ can be represented by ΔEᵥᵢ. Further, in order to specify the intermediate energy level, after these displays, the numbers of the intermediate energy levels can be described.

An energy difference between E_{c} and Eᵥ can be represented by E_{g}.

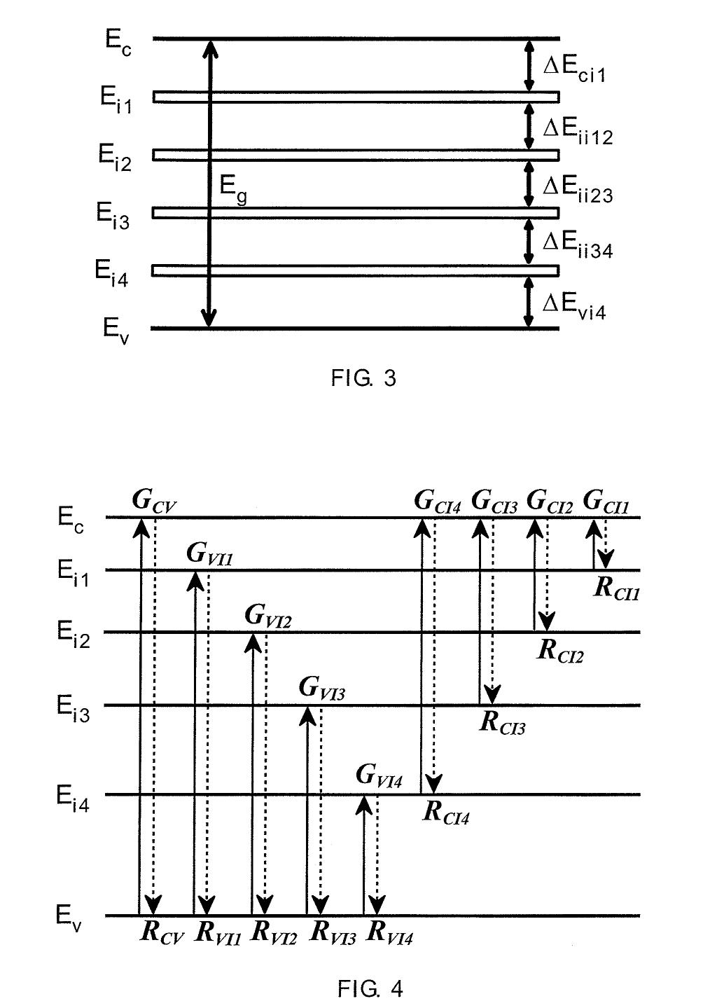

For example, a band diagram of the superlattice semiconductor layer 10 in a 6-levels intermediate-band solar cell can be expressed as shown in FIG. 3.

A carrier generation rate at the time when the electrons at Eᵥ are optically excited to E_{c} can be represented by “G_{CV}”, a carrier generation rate at the time when the electrons at Eᵥ are optically excited to Eᵢ can be represented by “G_{VI}”, and a carrier generation rate at the time when the electrons at Eᵢ are optically excited to E_{c} can be represented by G_{CI}. Further, in order to specify Eᵢ, subscript numbers of the intermediate energy level can be described after these symbols.

Emission recombination for recombining the electrons at E_{c} and the holes at Eᵥ and emitting light can be represented by R_{CV}, emission recombination for recombining the electrons at Eᵢ and the holes at Eᵥ and emitting light can be represented by “R_{VI}”, and emission recombination for transferring the electrons at E_{c} to Eᵢ and emitting light can be represented by “R_{CI}”. In order to specify subscript numbers of the intermediate energy levels can be described after these displays.

For example, a band diagram of the superlattice semiconductor layer 10 in a 6-levels intermediate-band solar cell can be shown in FIG. 4.

The band diagrams (energy band diagrams) used in this specification are shown in a conventionally manner unless particular reference is made. That is to say, the energy level is expressed based on the electron energy. The electrons are at the energy level such that the electrons transfer to lower energy, and this is a stable level. Further, the electron holes are put into a state such that the electron holes transfer to higher energy, and this is a stable state.

The superlattice semiconductor layer 10 having two or more such intermediate energy levels can be formed by, for example, adjusting a size of the quantum dots 7 included in the quantum dot layer 6 or a thickness of the quantum well layer 9. As described in an experiment 4 described later, for example, the quantum dots 7 of (2.7 nm, 2.7 nm and 9.0 nm) are formed by InAs_{0.7}Sb_{0.3} on the barrier layer 8 made of AlSb having a layer thickness of 2.0 nm, so that the two intermediate energy levels can be formed in the superlattice semiconductor layer 10. Further, the quantum dots of (2.5 nm, 2.5 nm, 8.5 nm) are formed by InAs on the barrier layer 8 made of AlSb_{0.5}As_{0.5} having a layer thickness of 2.0 nm, so that the two intermediate energy levels can be formed in the superlattice semiconductor layer 10.

When the superlattice semiconductor layer 10 has the two intermediate energy levels, the effective bandgap may be 1.0 eV or more to 3.5 eV or less. Such a bandgap can make the energy conversion efficiency higher than that of the solar cell having one intermediate energy level.

The superlattice semiconductor layer 10 having such a bandgap can be formed in a manner that, as described in the experiment 4, when, for example, InAs_{0.7}Sb_{0.3} is used for the quantum dots, AlSb is used for the barrier layer 8. When InAs is used for the quantum dots, AlSb_{0.5}As_{0.5} is used for the barrier layer 8. When a semiconductor material having a suitable physical property is selected or a mixed crystal ratio of the semiconductor material composing the superlattice semiconductor layer 10 is adjusted, the superlattice semiconductor layer 10 having a desired bandgap can be formed. The superlattice semiconductor layer 10 having a desired effective bandgap can be formed also by adjusting the size of the quantum dots 7 included in the quantum dot layer 6 composing the superlattice semiconductor layer 10 or the thickness of the barrier layer 8.

### 3. Method for Manufacturing the Solar Cell

In manufacturing of the solar cell according to the embodiment, the solar cell having the superlattice structure can be manufactured by using, for example, the molecular beam epitaxy (MBE) method or the organic metal chemistry gaseous phase growth method (MOCVD) with which control of a film thickness is excellent. The method for manufacturing the solar cell having the superlattice structure of FIG. 1 according to one embodiment will be described with reference to FIG. 1.

For example, after a p-GaAs substrate 1 is rinsed by an organic cleaning solvent, the p-GaAs substrate 1 is etched by a sulfate etching solution. Further, the substrate 1 is washed with running water, and is placed in an MOCVD device. The buffer layer 3 is formed on the substrate. The buffer layer 3 is for improving crystalline of a photoabsorption layer to be formed thereon. Thereafter, a p-type AlSbₓAs₁₋ₓ base layer (the p-type semiconductor layer) 4 and an AlSbₓAs₁₋ₓ layer to be the barrier layer 8 are crystal-grown into a thickness of 300 nm on the buffer layer 3, and the quantum dot layer 6 made of InAs is formed by using a self-organizing mechanism.

The crystal growths of the barrier layers 8 and the quantum dot layers 6 are repeated from the quantum dot layer 6 that is the nearest to the p-type semiconductor layer to the quantum dot layer 6 that is the nearest to the n-type semiconductor layer.

Thereafter, an n-type AlSbₓAs₁₋ₓ layer (the n-type semiconductor layer) 12 is crystal-grown to a thickness of 250 nm so that a pin structure is formed, and an AlAs layer is formed as the window layer 14.

An interdigitated electrode is formed on the contact layer 15 by the photolithography and lift-off process, and the contact layer 15 is selectively etched by using the interdigitated electrode as a mask so that the n-type electrode 17 is formed. As a result, the solar cell having the superlattice structure can be formed. The p-type electrode 18 is partially etched to the base layer 4, so as to be capable of being formed on the base layer 4.

Si can be used as an n-type dopant, and Be can be used as a p-type dopant. Au, for example, is used as an electrode material, and the electrode can be formed by vacuum deposition according to the resistance heat deposition method.

The embodiment described here is merely an example, and the materials of the substrate, the buffer layer, the quantum dots, the dopants and the electrodes used for the solar cell having the superlattice structure according to the embodiment, and cleaning solvents, the substrate processing temperatures and the manufacturing apparatuses used in the respective processes are not limited to those mentioned in the examples.

### Simulation Experiment 1

### [Experiment 1]

A simulation experiment was carried out by using a detailed balance model, so that the energy conversion efficiency was calculated. In order to describe this calculating method, band diagrams are shown in FIGS. 3 and 4. In this simulation experiment, the quantum dot layer was used as the quantum layer.

FIG. 3 is a band diagram of a superlattice semiconductor layer, which has four intermediate energy levels (the intermediate bands) and is included in the solar cell (6-levels intermediate-band solar cell) according to one embodiment of the present invention, and is an explanatory diagram describing a positional relationship of six levels.

FIG. 4 is a band diagram of the superlattice semiconductor layer, which has the four intermediate energy levels and is included in the solar cell (6-levels intermediate-band solar cell) according to one embodiment of the present invention, and is an explanatory diagram describing a relationship between a carrier generation rate “G” and an emission recombination “R”.

Photon flux included in an energy range from Eᵢₙᵢ to E_{fin} (Eᵢₙᵢ<E_{fin}) can be expressed by the following formula (1). Further, Eᵢₙᵢ and E_{fin} represent any energies that satisfy the relationship Eᵢₙᵢ<E_{fin}.

$$\begin{matrix}[ Mathematical Formula 1 ] & \\ N ( T , μ , {E}_{ini} , {E}_{fin} ) = \frac{2 π}{{h}^{3} {c}^{2}} {\int }_{{E}_{ini}}^{{E}_{fin}} \frac{{E}^{2}}{exp ( \frac{E - μ}{kT} ) - 1} d E & ( 1 )\end{matrix}$$

“N” represents the photon flux obtained based on the Planck's radiation Law. The character “h” represents a Planck's constant, “c” represents a light velocity in a vacuum, “μ” represents a chemical potential of an electron-electron hole pair, “k” represents a Boltlzman's constant, and “T” represents a temperature of substances.

When this photon flux is used, the carrier generation rate “G” and the emission recombination “R” between certain two levels in the six levels (the levels E_{c}, Eᵥ, Eᵢ₁, Eᵢ₂, Eᵢ₃ and Eᵢ₄) can be expressed by the following formulas (2) and (3).

[Mathematical Formula 2]

G=C₀H\dot{N}(Tₛ,0,Eᵢₙᵢ,E_{fin})+(1−C₀H)\dot{N}(T₀,0,Eᵢₙᵢ,E_{fin}), (2)

[Mathematical Formula 3]

R=\dot{N}(T₀,μ,Eᵢₙᵢ,E_{fin}) (3)

“C₀” represents a condensing magnification, “H” represents a constant geometrically determined by a distance between the sun and the earth, “Tₛ” represents a surface temperature of the sun, “T₀” represents a temperature of the solar cell.

Density “J” of a current taken out from an external electrode connected with the 6-levels intermediate-band solar cell to the outside by using these formulas can be expressed by the following formula (4). Since the intermediate bandwidth is very narrow and an energy range where electron transition is enabled between the intermediate bands is narrow (a difference between Eᵢₙᵢ and E_{fin} is small), the electron transition between the intermediate bands (the carrier generation and the emission recombination between any two levels of Eᵢ₁, Eᵢ₂, Eᵢ₃ and Eᵢ₄) is ignored.

$$\begin{matrix} [ Mathematical Formula 4 ] & \\ \frac{J}{q} = {G}_{CV} + {G}_{CI 1} + {G}_{CI 2} + {G}_{CI 3} + {G}_{CI 4} - {R}_{CV} - {R}_{CI 1} - {R}_{CI 2} - {C}_{CI 3} - {R}_{CI 4} & ( 4 )\end{matrix}$$

The character “q” represents elementary charge. Further, subscripts of the carrier generation rate “G” and the emission recombination “R” represent bands (the two energy levels at which the electron transition occurs) where transition occurs as shown in FIG. 4. For this reason, for example, subscript “CV” represents the electron transition between the energy level E_{c} and the energy level Eᵥ, subscript “CI1” represents the electron transition between the energy level E_{c} and the energy level Eᵢ₁, and the subscript “VI2” represents the electron transition between the energy level Eᵥ and the energy level Eᵢ₂. The other subscripts represent the two energy levels where the electron transition occurs according to the similar rule.

Since an electric current does not flow between the intermediate band (the intermediate energy level) and the external electrode, the electric current in the intermediate band becomes 0, and can be expressed by the following formulas (5) to (8).

[Mathematical Formula 5]

0=G_{VI1}−G_{CI1}−R_{VI1}+R_{CI1} (5)

[Mathematical Formula 6]

0=G_{VI2}−G_{CI2}−R_{VI2}+R_{CI2} (6)

[Mathematical Formula 7]

0=G_{VI3}−G_{CI3}−R_{VI3}+R_{CI3} (7)

[Mathematical Formula 8]

0=G_{VI4}−G_{CI4}−R_{VI4}+R_{CI4} (8)

The subscripts of the carrier generation rate “G” and the emission recombination “R” represent the two energy levels where the electron transition occurs according to the rule similar to the formula 4.

On the other hand, a solar energy “Pᵢₙ” can be expressed by the following formula (9).

$$\begin{matrix}[ Mathematical Formula 9 ] & \\ {P}_{in} = \frac{2 π {C}_{0} H}{{h}^{3} {c}^{2}} {\int }_{0}^{∞} \frac{{E}^{3}}{exp ( \frac{E}{{kT}_{s}} ) - 1} d E & ( 9 )\end{matrix}$$

At this time, when an output voltage is represented by “V” and an output current is represented by “J”, an energy conversion efficiency “η” is expressed by the following formula (10).

$$\begin{matrix}[ Mathematical Formula 10 ] & \\ η = \frac{JV}{{P}_{in}} & ( 10 )\end{matrix}$$

According to the above formulas, the maximum energy conversion efficiency of the 6-levels intermediate-band solar cell can be calculated. The 6-levels intermediate-band solar cell is described above, but the maximum energy conversion efficiency of another-level intermediate-band solar cell can be calculated according to a similar formula.

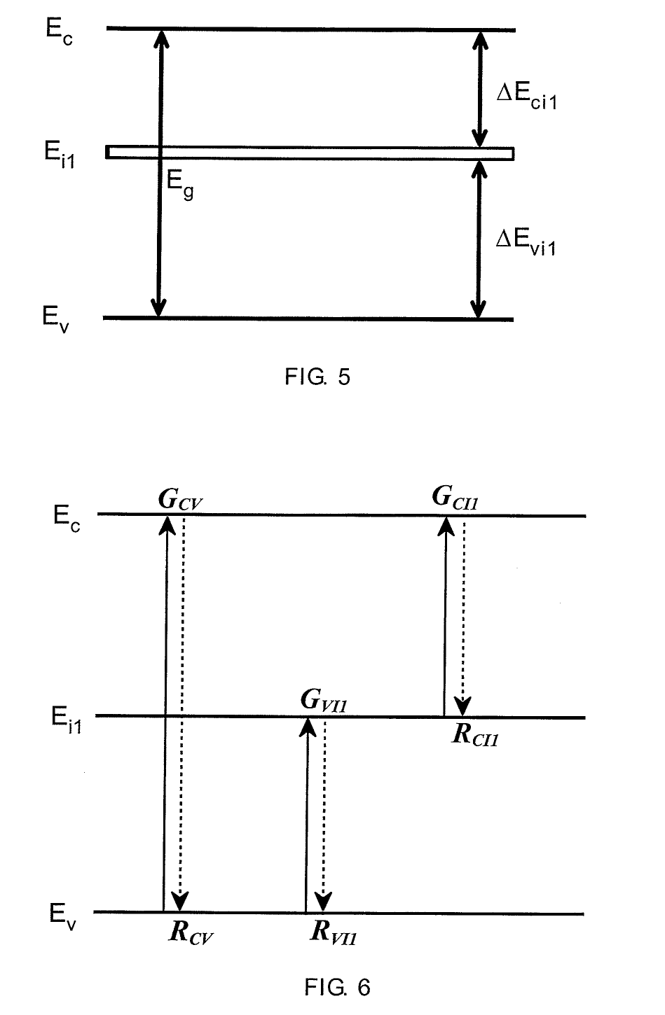

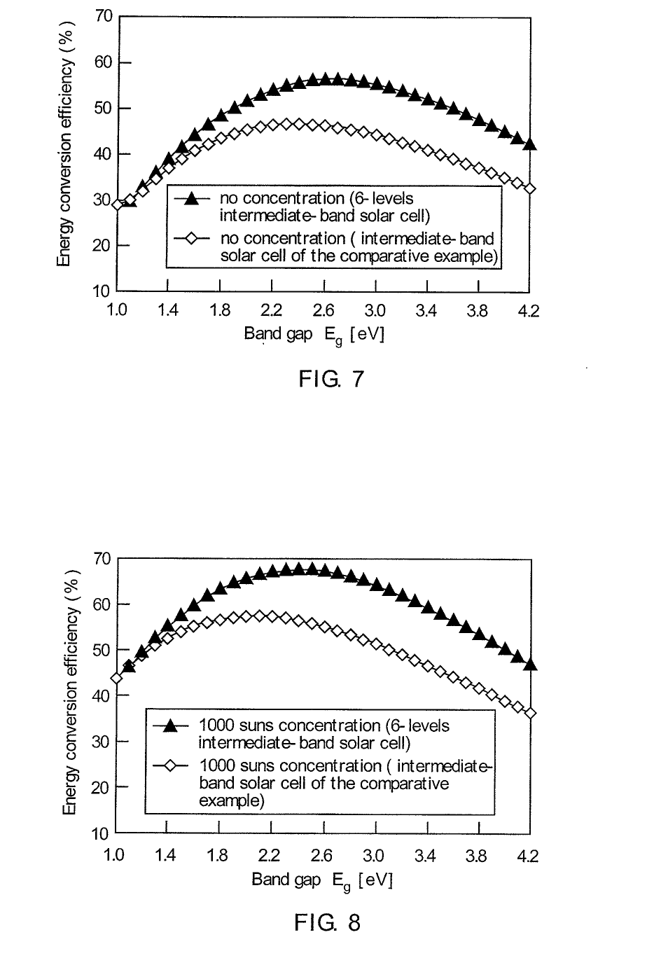

In the experiment 1, as to the 6-levels intermediate-band solar cell and the solar cell of a comparative example, the band gap E_{g} of the barrier layer and the energy level Eᵢ of the intermediate band were changed and the maximum energy conversion efficiency was calculated. Band diagrams of a 3-level intermediate-band solar cell having one intermediate energy level in the comparative example are shown in FIGS. 5 and 6, and the results of the experiment 1 are shown in FIGS. 7 and 8, and tables 1 and 2.

FIGS. 5 and 6 are the band diagrams of the superlattice semiconductor layer of the comparative example. That is to say, these diagrams show a case where a total of levels is three levels including the energy level at the bottom of the conduction band of the barrier layer composing the superlattice semiconductor layer, the energy level at the top of the valence band substantially regarded as one band in the quantum layers, and a level of one intermediate band formed by the quantum levels of the quantum dots (the solar cell comprising the superlattice semiconductor layer composed of the barrier layers and quantum dot layers, the superlattice semiconductor layer having the 3 levels is called as the intermediate-band solar cell of the comparative example). FIG. 7 is a graph showing a relationship between the band gap E_{g} and the maximum energy conversion efficiency in the case of non-condensing obtained by the simulation in the experiment 1. FIG. 8 is a graph illustrating a relationship between the band gap E_{g} and the energy conversion efficiency in the case of condensing obtained by the simulation of the experiment 1. Tables 1 and 2 show some results of the experiment 1 in the case where the energy conversion efficiency and the energy level of the 6-levels intermediate-band solar cell and the intermediate-band solar cell of the comparative example are compared. Table 1 shows the case where a condensing condition is “non-condensing”, and Table 2 shows a case where the condensing condition is “thousandfold condensing”.

In the simulation of the experiment 1, the calculation was made under the condition that Tₛ=6000 K, T₀=300 K, and the condensing magnification C₀ in the formulas (2) and (9) had two patterns such that C₀=1 and C₀=1000. The case where C₀=1 is described as “non-condensing” (FIG. 7), and the case where C₀=1000 is described as “thousandfold condensing” (FIG. 8).

With reference to FIG. 7, in the case of non-condensing, when the band gap of the barrier layer (a matrix semiconductor) of the 6-levels intermediate-band solar cell establishes a relationship: E_{g}<1.2 eV, its energy conversion efficiency is little different from that of intermediate-band solar cell in the comparative example.

On the other hand, when the band gap of the barrier layer is such that E_{g}≧1.2 eV, the energy conversion efficiency of the 6-levels intermediate-band solar cell might be higher than that of the intermediate-band solar cell in the comparative example by optimizing the band gap and intermediate band energy level (hereinafter this combination is called as a band lineup) (FIG. 7). When the band gap of the barrier layer is such that E_{g}=1.2 eV, an interval of the energy levels between the respective six levels and the nearest level becomes narrow to degree of a room-temperature energy. For this reason, it is more preferable that E_{g}≧1.3 eV in view of easy control of the energy level gap.

With reference to FIG. 7, when the band gap of the barrier layer is in a range where E_{g}=1.8 to 3.8 eV, the 6-levels intermediate-band solar cell can achieve the energy conversion efficiency that cannot be obtained in the intermediate-band solar cell of the comparative example. For example, the maximum energy conversion efficiency of the intermediate-band solar cell in the comparative example is about 46.7%, but the maximum energy conversion efficiency of the 6-levels intermediate-band solar cell is about 56.6% when the band gap E_{g} of the barrier layer is 2.6 to 2.7.

When the optimum band lineup is selected according to the results of FIG. 7, the 6-levels intermediate-band solar cell can achieve the energy conversion efficiency that cannot be obtained in the intermediate-band solar cell of the comparative example (the results in FIG. 7 can be understood also with reference to Table 1).

With reference to FIG. 8, similarly to the case of non-condensing, when the band gap of the barrier layer (referred to also as a matrix semiconductor) is such that E_{g}<1.1 eV, the energy conversion efficiency of the 6-levels intermediate-band solar cell is little different from that of the intermediate-band solar cell in the comparative example in the case of thousandfold condensing.

On the other hand, when the band gap of the barrier layer is such that E_{g}≧1.1 eV, the energy conversion efficiency of the 6-levels intermediate-band solar cell might be higher than that of the intermediate-band solar cell in the comparative example by optimizing the band gap and intermediate band energy level (FIG. 8). When the band gap of the barrier layer is such that 1.1≦E_{g}≦1.4 eV, the interval of the energy levels between the respective six levels and the nearest level might be narrow to a degree of a room-temperature energy. For this reason, it is preferable that E_{g}≧1.5 eV in view of easy control of the energy level interval.

With reference to FIG. 8, when the band gap E_{g} of the barrier layer is in a range of 1.5 to 3.5 eV, the energy conversion efficiency of the 6-levels intermediate-band solar cell that cannot be obtained in the intermediate-band solar cell of the comparative example is achieved. For example, the maximum energy conversion efficiency of the intermediate-band solar cell in the comparative example was about 57.3%, but when the band gap E_{g} of the barrier layer was 2.4 to 2.5 eV, the maximum energy conversion efficiency of the 6-levels intermediate-band solar cell was about 67.7%.

According to the results of FIG. 8, also in the case of the thousandfold condensing, the 6-levels intermediate-band solar cell can achieve the energy conversion efficiency that cannot be obtained in the intermediate-band solar cell of the comparative example by selecting the optimum band lineup (the results of FIG. 8 can be understood also with reference to Table 2).

TABLE 1
No Concentration

| | Efficiency | E_{g} | ΔE_{ci1} | ΔEᵢᵢ₁₂ | ΔEᵢᵢ₂₃ | ΔEᵢᵢ₃₄ | ΔEᵥᵢ₄ |
|---|---|---|---|---|---|---|---|
| 6-levels | 36.2 | 1.30 | 0.775 | 0.225 | 0.125 | 0.100 | 0.075 |
| 6-levels | 36.2 | 1.30 | 0.075 | 0.100 | 0.125 | 0.225 | 0.775 |
| 6-levels | 48.6 | 1.80 | 1.000 | 0.200 | 0.200 | 0.175 | 0.225 |
| 6-levels | 48.6 | 1.80 | 0.225 | 0.175 | 0.200 | 0.200 | 1.000 |
| 6-levels | 51.9 | 2.00 | 1.100 | 0.200 | 0.200 | 0.225 | 0.275 |
| 6-levels | 51.9 | 2.00 | 0.275 | 0.225 | 0.200 | 0.200 | 1.100 |
| 6-levels | 54.3 | 2.20 | 1.175 | 0.175 | 0.200 | 0.250 | 0.400 |
| 6-levels | 54.3 | 2.20 | 0.400 | 0.250 | 0.200 | 0.175 | 1.175 |
| 6-levels | 56.4 | 2.50 | 1.325 | 0.150 | 0.175 | 0.275 | 0.575 |
| 6-levels | 56.4 | 2.50 | 0.575 | 0.275 | 0.175 | 0.150 | 1.325 |
| 6-levels | 56.6 | 2.70 | 0.675 | 0.275 | 0.175 | 0.150 | 1.425 |
| 6-levels | 56.6 | 2.70 | 1.425 | 0.150 | 0.175 | 0.275 | 0.675 |
| 6-levels | 55.6 | 3.00 | 1.575 | 0.150 | 0.175 | 0.275 | 0.825 |
| 6-levels | 55.6 | 3.00 | 0.825 | 0.275 | 0.175 | 0.150 | 1.575 |
| 6-levels | 47.8 | 3.80 | 1.950 | 0.125 | 0.150 | 0.275 | 1.300 |
| 6-levels | 47.8 | 3.80 | 1.300 | 0.275 | 0.150 | 0.125 | 1.950 |
| | Efficiency | E_{g} | ΔE_{ci1} | ΔEᵥᵢ₁ | — | — | — |
| Comparative | 34.6 | 1.30 | 0.900 | 0.400 | — | — | — |
| Example | | | | | | | |
| Comparative | 34.6 | 1.30 | 0.400 | 0.900 | — | — | — |
| Example | | | | | | | |
| Comparative | 43.5 | 1.80 | 1.175 | 0.625 | — | — | — |
| Example | | | | | | | |
| Comparative | 43.5 | 1.80 | 0.625 | 1.175 | — | — | — |
| Example | | | | | | | |
| Comparative | 45.4 | 2.00 | 1.275 | 0.725 | — | — | — |
| Example | | | | | | | |
| Comparative | 45.4 | 2.00 | 0.725 | 1.275 | — | — | — |
| Example | | | | | | | |
| Comparative | 46.4 | 2.20 | 1.375 | 0.825 | — | — | — |
| Example | | | | | | | |
| Comparative | 46.4 | 2.20 | 0.825 | 1.375 | — | — | — |
| Example | | | | | | | |
| Comparative | 46.7 | 2.40 | 1.475 | 0.925 | — | — | — |
| Example | | | | | | | |
| Comparative | 46.7 | 2.40 | 0.925 | 1.475 | — | — | — |
| Example | | | | | | | |
| Comparative | 46.5 | 2.50 | 1.525 | 0.975 | — | — | — |
| Example | | | | | | | |
| Comparative | 46.5 | 2.50 | 0.975 | 1.525 | — | — | — |
| Example | | | | | | | |
| Comparative | 44.3 | 3.00 | 1.800 | 1.200 | — | — | — |
| Example | | | | | | | |
| Comparative | 44.3 | 3.00 | 1.200 | 1.800 | — | — | — |
| Example | | | | | | | |
| Comparative | 37.1 | 3.80 | 2.175 | 1.625 | — | — | — |
| Example | | | | | | | |
| Comparative | 37.1 | 3.80 | 1.625 | 2.175 | — | — | — |
| Example | | | | | | | |

TABLE 2

| | Efficiency | E_{g} | ΔE_{ci1} | ΔEᵢᵢ₁₂ | ΔEᵢᵢ₂₃ | ΔEᵢᵢ₃₄ | ΔEᵥᵢ₄ |
|---|---|---|---|---|---|---|---|
| 6-levels | 57.6 | 1.50 | 0.875 | 0.225 | 0.200 | 0.150 | 0.050 |
| 6-levels | 57.6 | 1.50 | 0.050 | 0.150 | 0.200 | 0.225 | 0.875 |
| 6-levels | 63.4 | 1.80 | 1.000 | 0.200 | 0.200 | 0.225 | 0.175 |
| 6-levels | 63.4 | 1.80 | 0.175 | 0.225 | 0.200 | 0.200 | 1.000 |
| 6-levels | 65.8 | 2.00 | 1.075 | 0.175 | 0.200 | 0.250 | 0.300 |
| 6-levels | 65.8 | 2.00 | 0.300 | 0.250 | 0.200 | 0.175 | 1.075 |
| 6-levels | 67.2 | 2.20 | 1.175 | 0.175 | 0.200 | 0.250 | 0.400 |
| 6-levels | 67.2 | 2.20 | 0.400 | 0.250 | 0.200 | 0.175 | 1.175 |
| 6-levels | 67.7 | 2.50 | 1.325 | 0.150 | 0.175 | 0.275 | 0.575 |
| 6-levels | 67.7 | 2.50 | 0.575 | 0.275 | 0.175 | 0.150 | 1.325 |
| 6-levels | 64.4 | 3.00 | 1.575 | 0.150 | 0.175 | 0.275 | 0.825 |
| 6-levels | 64.4 | 3.00 | 0.825 | 0.275 | 0.175 | 0.150 | 1.575 |
| 6-levels | 58.1 | 3.50 | 1.800 | 0.125 | 0.150 | 0.275 | 1.150 |
| 6-levels | 58.1 | 3.50 | 1.150 | 0.275 | 0.150 | 0.125 | 1.800 |
| | Efficiency | E_{g} | ΔE_{ci1} | ΔEᵥᵢ₁ | — | — | — |
| Comparative | 53.9 | 1.50 | 1.000 | 0.500 | — | — | — |
| Example | | | | | | | |
| Comparative | 53.9 | 1.50 | 0.500 | 1.000 | — | — | — |
| Example | | | | | | | |
| Comparative | 56.4 | 1.80 | 1.175 | 0.625 | — | — | — |
| Example | | | | | | | |
| Comparative | 56.4 | 1.80 | 0.625 | 1.175 | — | — | — |
| Example | | | | | | | |
| Comparative | 57.2 | 2.00 | 1.275 | 0.725 | — | — | — |
| Example | | | | | | | |
| Comparative | 57.2 | 2.00 | 0.725 | 1.275 | — | — | — |
| Example | | | | | | | |
| Comparative | 57.3 | 2.10 | 1.325 | 0.775 | — | — | — |
| Example | | | | | | | |
| Comparative | 57.3 | 2.10 | 0.775 | 1.325 | — | — | — |
| Example | | | | | | | |
| Comparative | 57.1 | 2.20 | 1.375 | 0.825 | — | — | — |
| Example | | | | | | | |
| Comparative | 57.1 | 2.20 | 0.825 | 1.375 | — | — | — |
| Example | | | | | | | |
| Comparative | 55.7 | 2.50 | 1.525 | 0.975 | — | — | — |
| Example | | | | | | | |
| Comparative | 55.7 | 2.50 | 0.975 | 1.525 | — | — | — |
| Example | | | | | | | |
| Comparative | 51.2 | 3.00 | 1.800 | 1.200 | — | — | — |
| Example | | | | | | | |
| Comparative | 51.2 | 3.00 | 1.200 | 1.800 | — | — | — |
| Example | | | | | | | |
| Comparative | 45.3 | 3.50 | 2.025 | 1.475 | — | — | — |
| Example | | | | | | | |
| Comparative | 45.3 | 3.50 | 1.475 | 2.025 | — | — | — |
| Example | | | | | | | |

In tables 1 and 2, ΔE represents the energy difference between the two energy levels (bands), and for example, ΔE_{ci1} represents an energy difference between the energy level E_{c} and the energy level Eᵢ₁ (see FIG. 3). Alphameric characters described after ΔE represent the two energy levels. The other descriptions such as ΔEᵢᵢ₁₂ and tables 3 to 6 are based on the similar rule.

With reference to Tables 1 and 2, when a comparison is made based on the same E_{g}, the optimum band lineup of the 6-levels intermediate-band solar cell that exceeds the conversion efficiency of the intermediate-band solar cell in the comparative example is such that ΔE_{ci1}≧0.05 eV or ΔEᵥᵢ₄≧0.05 eV. Further, this optimum band lineup is such that |(ΔE_{ci1}−ΔEᵥᵢ₄)|≧0.65 eV. Further, MIN (ΔEᵢᵢ₁₂, ΔEᵢᵢ₂₃ and ΔEᵢᵢ₃₄)≧0.10 eV.

MIN (A, B, C) means a numerical value that is the smallest in numerical values A, B and C. In this specification, MIN (A, B, . . . ) means a numerical value that is the smallest in parenthetic numerical values.

With reference to Tables 1 and 2, in comparison with the maximum conversion efficiency of the intermediate-band solar cell in the comparative example, the optimum band lineup of the 6-levels intermediate-band solar cell that exceeds the maximum conversion efficiency of the intermediate-band solar cell in the comparative example is such that ΔE_{ci1}≧0.05 eV or ΔEᵥᵢ₄≧0.05 eV. This optimum band lineup is such that |(ΔE_{ci1}−ΔEᵥᵢ₄)|≧0.65 eV. Further, MIN (ΔEᵢᵢ₁₂, ΔEᵢᵢ₂₃, ΔEᵢᵢ₃₄)≧0.125 eV.

For example, when the 6-levels intermediate-band solar cell is composed of the quantum dots and a band offset between the quantum dots and the barrier layer in the valence band is 0, or the quantum level formed in the valence band can be regarded as one band (namely, when the four intermediate-band levels are produced by using a potential due to the band offset of the conduction bands), as ΔEᵥᵢ₄ is larger (ΔE_{ci1}+ΔEᵢᵢ₁₂+ΔEᵢᵢ₂₃+ΔEᵢᵢ₃₄ is smaller), an energy level Eᵢ₄ of the lowest intermediate band is closer to the bottom of the conduction band in the barrier layer, and the wave function of the electrons in the quantum dot layer easily interacts with the wave function of the adjacent quantum dot layer greatly. Therefore, the intermediate bands Eᵢ₁, Eᵢ₂, Eᵢ₃ and Eᵢ₄ are easily formed, and carriers easily transfer. Form such a viewpoint, it is preferable that ΔEᵥᵢ₄≧(E_{g}/2) eV, and when tables 1 and 2 are reviewed, the optimum band lineup of the 6-levels intermediate-band solar cell is such that ΔEᵥᵢ₄≧(E_{g}/2+0.05) eV. In a form that satisfies such a formula, when the four intermediate bands are formed by using a potential between the conduction band bottom of the quantum dot layer and the conduction band bottom of the barrier layer, the energy level of the lowest intermediate band is close to the conduction band bottom of the barrier layer. For this reason, the wave function of the electrons of the quantum dot layer in the superlattice structure easily interacts with the wave function of the adjacent quantum dot layers greatly. For this reason, the intermediate band obtained by joining the quantum levels into one is easily formed, and the carriers easily transfer.

For example, when E_{g}=2.5 eV in the 6-levels intermediate-band solar cell in the case of thousandfold condensing, the band lineup that achieves the energy conversion efficiency of 67.7%, namely, the combination of ΔE_{ci1} and ΔEᵥᵢ₄ is such that (ΔE_{ci1}, ΔEᵥᵢ₄)=(1.325 eV, 0.575 eV) (0.575 eV, 1.325 eV). A preferable combination that satisfies the above lineup is (ΔE_{ci1}, ΔEᵥᵢ₄)=(0.575 eV, 1.325 eV) based on the above condition that ΔEᵥᵢ₄ (E_{g}/2+0.05) eV.

### [Experiment 2]

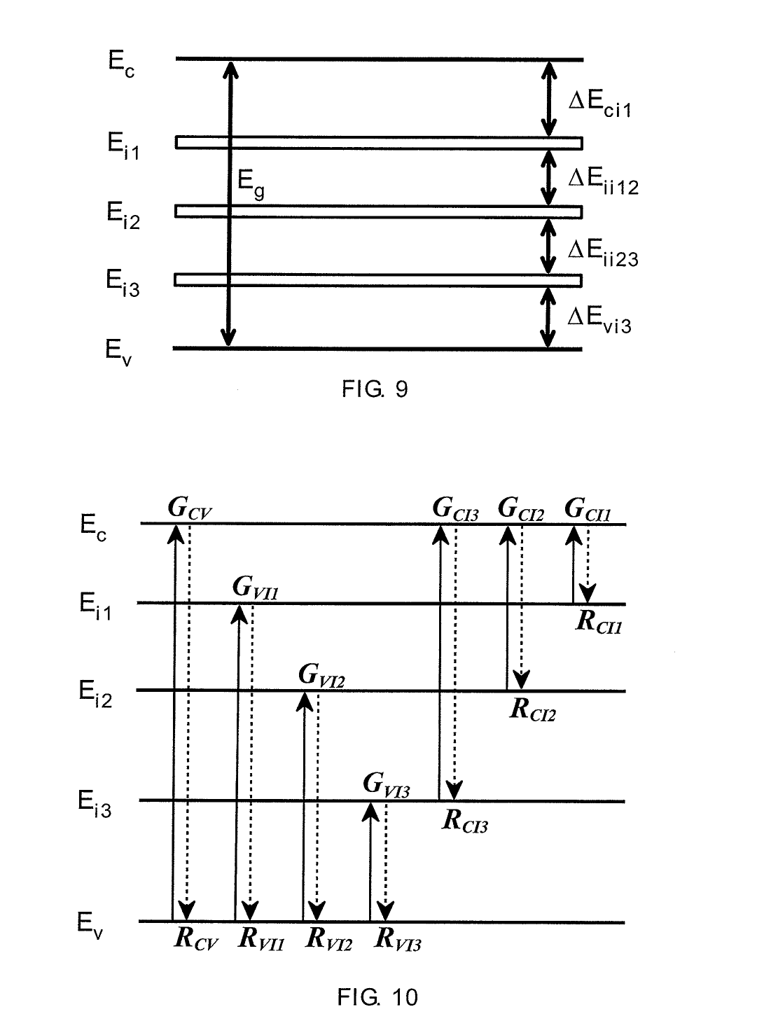

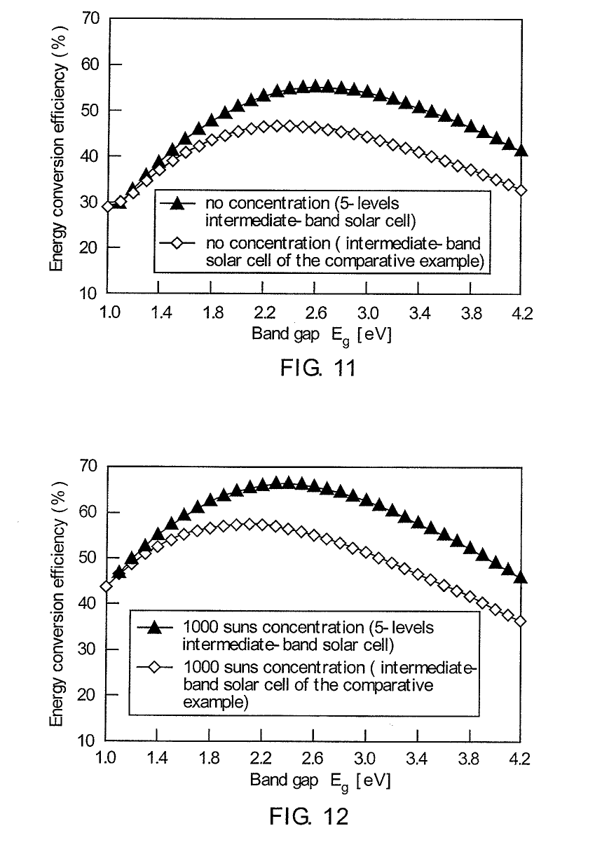

A simulation experiment was conducted on the solar cell (5-levels intermediate-band solar cell) according to a calculating method similar to that in the experiment 1, the solar cell having five levels comprising: the energy level at the bottom (the lowest portion) of the conduction band in the barrier layer composing the superlattice semiconductor layer; the energy level at the top (the highest portion) of the valence band in the barrier layer; and the three energy levels of the three intermediate bands formed by the quantum level of the quantum dots. In this simulation experiment, some examples of the solar cell having the five levels were given, and the energy conversion efficiency was calculated. Band diagrams of the superlattice semiconductor layer in this solar cell are shown in FIGS. 9 and 10, and experimental results are shown in FIGS. 11 and 12, and tables 3 and 4.

FIG. 9 is a band diagram of a superlattice semiconductor layer, which has three intermediate energy levels and is included in the solar cell according to one embodiment of the present invention, and is an explanatory diagram describing a positional relationship of five levels. FIG. 10 is a band diagram of the superlattice semiconductor layer, which has three intermediate energy levels and is included in the solar cell according to one embodiment of the present invention, and is an explanatory diagram describing a relationship between the carrier generation rate “G” and the emission recombination “R”.

FIG. 11 is a graph showing a relationship between the band gap E_{g} and the maximum energy conversion efficiency obtained by the simulation in the experiment 2 in the case of the non-condensing. FIG. 12 is a graph showing a relationship between the band gap E_{g} and the maximum energy conversion efficiency obtained by the simulation in the experiment 2 in the case of condensing.

Tables 3 and 4 show some results of the experiment 2 in a case where the energy conversion efficiency and the energy level are compared between the 5-levels intermediate-band solar cell and the intermediate-band solar cell in the comparative example. Table 3 shows a case where the condensing condition is “non-condensing”, and Table 4 shows a case where the condensing condition is “thousandfold condensing”.

Also in the simulation of the experiment 2, the calculation is made in a state that Tₛ=6000 K and T₀=300 K similarly to the simulation in the experiment 1, and the condensing magnification C₀ in the formulas (2) and (9) has two patterns such that C₀=1 and C₀=1000. The case where C₀=1 is described as “non-condensing” (FIG. 11), and the case where C₀=1000 is described as “thousandfold condensing” (FIG. 12).

With reference to FIG. 11, in the case of non-condensing, when the band gap of the barrier layer (a matrix semiconductor) is such that E_{g}<1.2 eV, the energy conversion efficiency of the 5-levels intermediate-band solar cell is little different from that of the intermediate-band solar cell in the comparative example.

On the other hand, when the band gap of the barrier layer is such that E_{g}≧1.2 eV, the energy conversion efficiency of the 5-levels intermediate-band solar cell might be higher than that of the intermediate-band solar cell in the comparative example by optimizing the band gap and intermediate band energy level (FIG. 11). When the band gap E_{g} of the barrier layer is 1.2 eV, the interval of the energy levels between each of the five levels and the nearest level becomes narrow to a degree of a room-temperature energy. For this reason, it is preferable that E_{g}≧1.3 eV in view of easy control of the energy level interval.

With reference to FIG. 11, when the band gap E_{g} of the barrier layer is in a range of 1.8 to 3.8 eV, the 5-levels intermediate-band solar cell achieves the energy conversion efficiency that cannot be obtained in the intermediate-band solar cell of the comparative example. For example, the maximum energy conversion efficiency of the intermediate-band solar cell in the comparative example is about 46.7%, but when the band gap E_{g} of the barrier layer is 2.6 to 2.7 eV, the maximum energy conversion efficiency of the 5-levels intermediate-band solar cell is about 55.4%.

According to the result in FIG. 11, when the optimum band lineup is selected, the 5-levels intermediate-band solar cell achieves the energy conversion efficiency that cannot be obtained in the intermediate-band solar cell of the comparative example (the result in FIG. 11 can be understood also with reference to Table 3).

With reference to FIG. 12, in the case of thousandfold condensing, similarly to the case of non-condensing, when the band gap of the barrier layer (the matrix semiconductor) is such that E_{g}<1.1 eV, the energy conversion efficiency of the 5-levels intermediate-band solar cell is little different from that of the intermediate-band solar cell in the comparative example.

On the other hand, when the band gap of the barrier layer is such that E_{g}≧1.1 eV, the energy conversion efficiency of the 5-levels intermediate-band solar cell might be higher than that of the intermediate-band solar cell in the comparative example by optimizing the band gap and intermediate band energy level (FIG. 12).

With reference to FIG. 12, when the band gap E_{g} of the barrier layer is in a range of 1.5 to 3.4 eV, the 5-levels intermediate-band solar cell achieves the energy conversion efficiency that cannot be obtained in the intermediate-band solar cell of the comparative example. For example, the maximum energy conversion efficiency of the intermediate-band solar cell in the comparative example is about 57.3%, but when the band gap E_{g} of the barrier layer is 2.3 to 2.4 eV, the maximum energy conversion efficiency of the 5-levels intermediate-band solar cell is about 66.5%.

According to the result in FIG. 12, also in the case of thousandfold condensing, when the optimum band lineup is selected, the 5-levels intermediate-band solar cell achieves the energy conversion efficiency that cannot be obtained in the intermediate-band solar cell in the comparative example (the result in FIG. 12 can be understood also with reference to Table 4).

TABLE 3

| | Efficiency | E_{g} | ΔE_{ci1} | ΔEᵢᵢ₁₂ | ΔEᵢᵢ₂₃ | ΔEᵥᵢ₃ |
|---|---|---|---|---|---|---|
| 5-levels | 36.1 | 1.30 | 0.775 | 0.225 | 0.150 | 0.150 |
| 5-levels | 36.1 | 1.30 | 0.150 | 0.150 | 0.225 | 0.775 |
| 5-levels | 48.0 | 1.80 | 1.025 | 0.250 | 0.250 | 0.275 |
| 5-levels | 48.0 | 1.80 | 0.275 | 0.250 | 0.250 | 1.025 |
| 5-levels | 51.1 | 2.00 | 0.350 | 0.275 | 0.250 | 1.125 |
| 5-levels | 51.1 | 2.00 | 1.125 | 0.250 | 0.275 | 0.350 |
| 5-levels | 53.5 | 2.20 | 0.475 | 0.300 | 0.225 | 1.200 |
| 5-levels | 53.5 | 2.20 | 1.200 | 0.225 | 0.300 | 0.475 |
| 5-levels | 55.3 | 2.50 | 0.625 | 0.300 | 0.225 | 1.350 |
| 5-levels | 55.3 | 2.50 | 1.350 | 0.225 | 0.300 | 0.625 |
| 5-levels | 55.4 | 2.60 | 0.675 | 0.300 | 0.225 | 1.400 |
| 5-levels | 55.4 | 2.60 | 1.400 | 0.225 | 0.300 | 0.675 |
| 5-levels | 54.3 | 3.00 | 0.900 | 0.300 | 0.200 | 1.600 |
| 5-levels | 54.3 | 3.00 | 1.600 | 0.200 | 0.300 | 0.900 |
| 5-levels | 46.9 | 3.80 | 1.350 | 0.300 | 0.175 | 1.975 |
| 5-levels | 46.9 | 3.80 | 1.975 | 0.175 | 0.300 | 1.350 |
| | Efficiency | E_{g} | ΔE_{ci1} | ΔEᵥᵢ₁ | — | — |
| Comparative | 34.6 | 1.30 | 0.900 | 0.400 | — | — |
| Example | | | | | | |
| Comparative | 34.6 | 1.30 | 0.400 | 0.900 | — | — |
| Example | | | | | | |
| Comparative | 43.5 | 1.80 | 1.175 | 0.625 | — | — |
| Example | | | | | | |
| Comparative | 43.5 | 1.80 | 0.625 | 1.175 | — | — |
| Example | | | | | | |
| Comparative | 45.4 | 2.00 | 1.275 | 0.725 | — | — |
| Example | | | | | | |
| Comparative | 45.4 | 2.00 | 0.725 | 1.275 | — | — |
| Example | | | | | | |
| Comparative | 46.4 | 2.20 | 1.375 | 0.825 | — | — |
| Example | | | | | | |
| Comparative | 46.4 | 2.20 | 0.825 | 1.375 | — | — |
| Example | | | | | | |
| Comparative | 46.7 | 2.40 | 1.475 | 0.925 | — | — |
| Example | | | | | | |
| Comparative | 46.7 | 2.40 | 0.925 | 1.475 | — | — |
| Example | | | | | | |
| Comparative | 46.5 | 2.50 | 1.525 | 0.975 | — | — |
| Example | | | | | | |
| Comparative | 46.5 | 2.50 | 0.975 | 1.525 | — | — |
| Example | | | | | | |
| Comparative | 44.3 | 3.00 | 1.800 | 1.200 | — | — |
| Example | | | | | | |
| Comparative | 44.3 | 3.00 | 1.200 | 1.800 | — | — |
| Example | | | | | | |
| Comparative | 37.1 | 3.80 | 2.175 | 1.625 | — | — |
| Example | | | | | | |
| Comparative | 37.1 | 3.80 | 1.625 | 2.175 | — | — |
| Example | | | | | | |

TABLE 4

| | Efficiency | E_{g} | ΔE_{ci1} | ΔEᵢᵢ₁₂ | ΔEᵢᵢ₂₃ | ΔEᵥᵢ₃ |
|---|---|---|---|---|---|---|
| 5-levels | 47.1 | 1.10 | 0.675 | 0.225 | 0.150 | 0.050 |
| 5-levels | 47.1 | 1.10 | 0.050 | 0.150 | 0.225 | 0.675 |
| 5-levels | 57.5 | 1.50 | 0.875 | 0.250 | 0.225 | 0.150 |
| 5-levels | 57.5 | 1.50 | 0.150 | 0.225 | 0.250 | 0.875 |
| 5-levels | 59.5 | 1.60 | 0.175 | 0.250 | 0.250 | 0.925 |
| 5-levels | 59.5 | 1.60 | 0.925 | 0.250 | 0.250 | 0.175 |
| 5-levels | 64.9 | 2.00 | 1.100 | 0.225 | 0.275 | 0.400 |
| 5-levels | 64.9 | 2.00 | 0.400 | 0.275 | 0.225 | 1.100 |
| 5-levels | 66.1 | 2.20 | 1.200 | 0.225 | 0.300 | 0.475 |
| 5-levels | 66.1 | 2.20 | 0.475 | 0.300 | 0.225 | 1.200 |
| 5-levels | 66.5 | 2.40 | 0.575 | 0.300 | 0.225 | 1.300 |
| 5-levels | 66.5 | 2.40 | 1.300 | 0.225 | 0.300 | 0.575 |
| 5-levels | 66.4 | 2.50 | 1.350 | 0.225 | 0.300 | 0.625 |
| 5-levels | 66.4 | 2.50 | 0.625 | 0.300 | 0.225 | 1.350 |
| 5-levels | 62.9 | 3.00 | 1.600 | 0.200 | 0.300 | 0.900 |
| 5-levels | 62.9 | 3.00 | 0.900 | 0.300 | 0.200 | 1.600 |
| 5-levels | 58.1 | 3.40 | 1.775 | 0.175 | 0.300 | 1.150 |
| 5-levels | 58.1 | 3.40 | 1.150 | 0.300 | 0.175 | 1.775 |
| | Efficiency | E_{g} | ΔE_{ci1} | ΔEᵥᵢ₁ | — | — |
| Comparative | 46.3 | 1.10 | 0.750 | 0.350 | — | — |
| Example | | | | | | |
| Comparative | 46.3 | 1.10 | 0.350 | 0.750 | — | — |
| Example | | | | | | |
| Comparative | 53.9 | 1.50 | 1.000 | 0.500 | — | — |
| Example | | | | | | |
| Comparative | 53.9 | 1.50 | 0.500 | 1.000 | — | — |
| Example | | | | | | |
| Comparative | 55.0 | 1.60 | 1.050 | 0.550 | — | — |
| Example | | | | | | |
| Comparative | 55.0 | 1.60 | 0.550 | 1.050 | — | — |
| Example | | | | | | |
| Comparative | 57.2 | 2.00 | 1.275 | 0.725 | — | — |
| Example | | | | | | |
| Comparative | 57.2 | 2.00 | 0.725 | 1.275 | — | — |
| Example | | | | | | |
| Comparative | 57.3 | 2.10 | 1.325 | 0.775 | — | — |
| Example | | | | | | |
| Comparative | 57.3 | 2.10 | 0.775 | 1.325 | — | — |
| Example | | | | | | |
| Comparative | 57.1 | 2.20 | 1.375 | 0.825 | — | — |
| Example | | | | | | |
| Comparative | 57.1 | 2.20 | 0.825 | 1.375 | — | — |
| Example | | | | | | |
| Comparative | 55.7 | 2.50 | 1.525 | 0.975 | — | — |
| Example | | | | | | |
| Comparative | 55.7 | 2.50 | 0.975 | 1.525 | — | — |
| Example | | | | | | |
| Comparative | 51.2 | 3.00 | 1.800 | 1.200 | — | — |
| Example | | | | | | |
| Comparative | 51.2 | 3.00 | 1.200 | 1.800 | — | — |
| Example | | | | | | |
| Comparative | 46.5 | 3.40 | 1.975 | 1.425 | — | — |
| Example | | | | | | |
| Comparative | 46.5 | 3.40 | 1.975 | 1.425 | — | — |
| Example | | | | | | |

With reference to Tables 3 and 4, when the comparison is made in case of the same E_{g}, the optimum band lineup of the 5-levels intermediate-band solar cell that exceeds the conversion efficiency of the intermediate-band solar cell in the comparative example is such that ΔE_{ci1}≧0.05 eV or ΔEᵥᵢ₃≧0.05 eV. Further, the optimum band lineup is such that |(ΔE_{ci1}−ΔEᵥᵢ₃)|≧0.625 eV. Further, MIN(ΔEᵢᵢ₁₂, ΔEᵢᵢ₂₃)≧0.15 eV.

With reference to Tables 3 and 4, in comparison with the maximum conversion efficiency of the intermediate-band solar cell in the comparative example, the optimum band lineup of the 5-levels intermediate-band solar cell that exceeds the maximum conversion efficiency of the intermediate-band solar cell in the comparative example is such that ΔE_{ci1}≧0.175 eV or ΔEᵥᵢ₃≧0.175 eV. The optimum band lineup is such that |(ΔE_{ci1}−ΔEᵥᵢ₃)|≧0.625 eV. Further, MIN (ΔEᵢᵢ₁₂, ΔEᵢᵢ₂₃)≧0.175 eV.

For example, when 5-levels intermediate-band solar cell is composed of the quantum dots, the band offset between the quantum dots and the barrier layer in the valence band is 0 or the quantum level formed in the valence band can be regarded as one band (namely, the three intermediate-band levels are formed by using a potential formed due to a conduction band offset), as ΔEᵥᵢ₃ is larger (ΔE_{ci1}+ΔEᵢᵢ₁₂+ΔEᵢᵢ₂₃ is smaller), the energy level Eᵢ₃ of the lowest intermediate band is closer to the bottom of the conduction band of the barrier layer, and the wave function of the electrons in the quantum dot layer easily interacts with the wave function of the adjacent quantum dot layer greatly. Therefore, the intermediate bands Eᵢ₁, Eᵢ₂, Eᵢ₃ are easily formed, and the carriers easily transfer. When tables 3 and 4 are reviewed from such a viewpoint, the optimum band lineup of the 5-levels intermediate-band solar cell is preferably such that ΔEᵥᵢ₃≧(E_{g}/2+0.075) eV.

For example, when E_{g}=2.4e V in the 5-levels intermediate-band solar cell in the case of thousandfold condensing, the band lineup that attains the energy conversion efficiency of 63.5%, namely, a combination of ΔE_{ci1} and ΔEᵥᵢ₃ is such that (ΔE_{ci1}, ΔEᵥᵢ₃)=(1.30 eV, 0.575 eV) (0.575 eV, 1.30 eV). A preferable combination that satisfies the above band lineup is (ΔE_{ci1}, ΔEᵥᵢ₃)=(0.575 eV, 1.30 eV) based on the above condition that ΔEᵥᵢ₃ (E_{g}/2+0.075) eV.

### [Experiment 3]

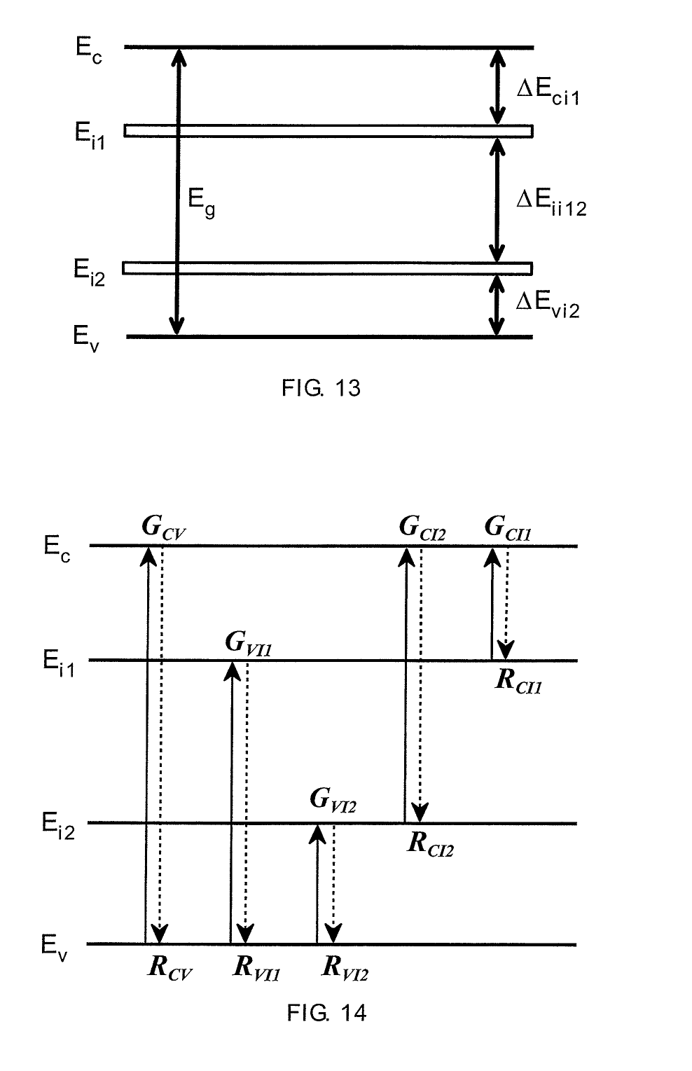

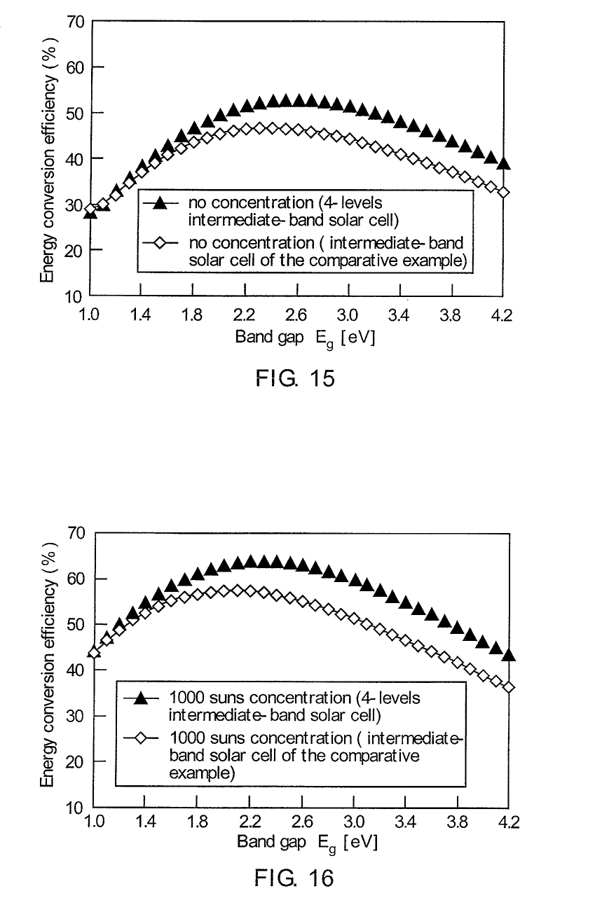

A simulation experiment was conducted on the solar cell (4-levels intermediate-band solar cell) according to a calculating method similar to those in the experiment 1 and the experiment 2, the solar cell having four levels comprising: the energy level at the bottom (the lowest portion) of the conduction band in the barrier layer composing the superlattice semiconductor layer; the energy level at the top (the highest portion) of the valence band in the barrier layer; and the two energy levels of the two intermediate bands formed by the quantum level of the quantum dots. In this simulation experiment, some solar cells having four levels were exemplified, and their energy conversion efficiencies were calculated. Band diagrams of the superlattice semiconductor layer in the solar cell are shown in FIGS. 13 and 14, and experimental results are shown in FIGS. 15 and 16 and tables 5 and 6.

FIG. 13 is a band diagram of a superlattice semiconductor layer, which has two intermediate energy levels and is included in the solar cell (4-levels intermediate-band solar cell) according to one embodiment of the present invention, and is an explanatory diagram describing a positional relationship between four levels. FIG. 14 is a band diagram of the superlattice semiconductor layer, which has two intermediate energy levels and is included in the solar cell (4-levels intermediate-band solar cell) according to one embodiment of the present invention, and is an explanatory diagram describing a relationship between the carrier generation rate “G” and the emission recombination “R”.

FIG. 15 is a graph showing a relationship between the band gap E_{g} and the maximum energy conversion efficiency obtained by the simulation of the experiment 3 in the case of non-condensing. FIG. 16 is a graph showing a relationship between the band gap E_{g} and the maximum energy conversion efficiency obtained by the simulation of the experiment 3 in the case of condensing.

Tables 5 and 6 show some results of the experiment 3 when the energy conversion efficiency and the energy level are compared between the 4-levels intermediate-band solar cell and the intermediate-band solar cell of the comparative example. Table 5 shows the case where the condensing condition is “non-condensing”, and table 6 shows the case where the condensing condition is “thousandfold condensing”.

In tables 5 and 6, a string of ΔE_{ci1}(ΔEᵥᵢ₂) and a string of ΔEᵥᵢ₂(ΔE_{ci1}) are present. When one value is ΔE_{ci1}, the other value is ΔEᵥᵢ₂, and when one value is ΔEᵥᵢ₂, the other value is ΔE_{ci1}.

Also in the simulation of the experiment 3, similarly to the simulations in the experiment 1 and the experiment 2, the calculation is made in the state that Tₛ=6000 K and T₀=300 K, and the condensing magnification C₀ in the formula (7) has two patterns such that C₀=1 and C₀=1000. The case where C₀=1 is described as “non-condensing” (FIG. 15), and the case where C₀=1000 is described as “thousandfold condensing (FIG. 16).

With reference to FIG. 15, in the case of non-condensing, when the band gap of the barrier layer (the matrix semiconductor) is such that E_{g}<1.2 eV, the energy conversion efficiency of the 4-levels intermediate-band solar cell is little different from that of the intermediate-band solar cell in the comparative example.

On the other hand, when the band gap of the barrier layer is such that E_{g}≧1.2 eV, the energy conversion efficiency of the 4-levels intermediate-band solar cell might be higher than that of the intermediate-band solar cell in the comparative example by optimizing the band gap and intermediate band energy level (FIG. 15).

With reference to FIG. 15, when the band gap E_{g} of the barrier layer is in a range of 1.8 to 3.5 eV, the 4-levels intermediate-band solar cell achieves the energy conversion efficiency that cannot be obtained in the intermediate-band solar cell of the comparative example. For example, the maximum energy conversion efficiency of the intermediate-band solar cell in the comparative example is about 46.7%, but when the band gap E_{g} of the barrier layer is 2.6 eV, the maximum energy conversion efficiency of the 4-levels intermediate-band solar cell is about 53.0%.

According to the result in FIG. 15, when the optimum band lineup is selected, the 4-levels intermediate-band solar cell achieves the energy conversion efficiency that cannot be obtained in the intermediate-band solar cell of the comparative example (the result in FIG. 15 can be understood also with reference to table 5).

With reference to FIG. 16, in the case of thousandfold condensing, the band gap of the barrier layer is such that E_{g}≧1.0 eV, the energy conversion efficiency of the 4-levels intermediate-band solar cell might be higher than that of the intermediate-band solar cell in the comparative example by optimizing the intermediate band energy level (FIG. 16).

With reference to FIG. 16, when the band gap E_{g} of the barrier layer is in a range of 1.6 to 3.2 eV, the 4-levels intermediate-band solar cell achieves the energy conversion efficiency that cannot be obtained in the intermediate-band solar cell of the comparative example. For example, the maximum energy conversion efficiency of the intermediate-band solar cell in the comparative example is about 57.3%, but when the band gap E_{g} of the barrier layer is 2.3 eV, the maximum energy conversion efficiency of the 4-levels intermediate-band solar cell is about 63.8%.

According to the result in FIG. 16, also in the case of thousandfold condensing, when the optimum band lineup is selected, the 4-levels intermediate-band solar cell achieves the energy conversion efficiency that cannot be obtained in the intermediate-band solar cell of the comparative example (the result in FIG. 16 can be understood also with reference to table 6).

TABLE 5

| | | | Δ E_{ci1} | | Δ Eᵥᵢ₂ |
|---|---|---|---|---|---|
| | Efficiency | E_{g} | (Δ Eᵥᵢ₂) | Δ Eᵢᵢ₁₂ | (Δ E_{ci1}) |
| 4- levels | 33.1 | 1.20 | 0.775 | 0.250 | 0.175 |
| 4- levels | 33.1 | 1.20 | 0.425 | 0.600 | 0.175 |
| 4- levels | 46.7 | 1.80 | 1.075 | 0.350 | 0.375 |
| 4- levels | 46.7 | 1.80 | 0.725 | 0.700 | 0.375 |
| 4- levels | 49.6 | 2.00 | 1.150 | 0.350 | 0.500 |
| 4- levels | 49.6 | 2.00 | 0.850 | 0.650 | 0.500 |
| 4- levels | 51.6 | 2.20 | 1.250 | 0.350 | 0.600 |
| 4- levels | 51.6 | 2.20 | 0.950 | 0.650 | 0.600 |
| 4- levels | 52.9 | 2.50 | 1.400 | 0.350 | 0.750 |
| 4- levels | 52.9 | 2.50 | 1.100 | 0.650 | 0.750 |
| 4- levels | 53.0 | 2.60 | 1.450 | 0.350 | 0.800 |
| 4- levels | 53.0 | 2.60 | 1.150 | 0.650 | 0.800 |
| 4- levels | 51.6 | 3.00 | 1.650 | 0.375 | 0.975 |
| 4- levels | 51.6 | 3.00 | 1.350 | 0.675 | 0.975 |
| 4- levels | 47.3 | 3.50 | 1.875 | 0.350 | 1.275 |
| 4- levels | 47.3 | 3.50 | 1.625 | 0.600 | 1.275 |
| | Efficiency | E_{g} | Δ E_{ci1} | Δ Eᵥᵢ₁ | — |
| Comparative | 32.0 | 1.20 | 0.825 | 0.375 | — |
| Example | | | | | |
| Comparative | 32.0 | 1.20 | 0.375 | 0.825 | — |
| Example | | | | | |
| Comparative | 43.5 | 1.80 | 1.175 | 0.625 | — |
| Example | | | | | |
| Comparative | 43.5 | 1.80 | 0.625 | 1.175 | — |
| Example | | | | | |
| Comparative | 45.4 | 2.00 | 1.275 | 0.725 | — |
| Example | | | | | |
| Comparative | 45.4 | 2.00 | 0.725 | 1.275 | — |
| Example | | | | | |
| Comparative | 46.4 | 2.20 | 1.375 | 0.825 | — |
| Example | | | | | |
| Comparative | 46.4 | 2.20 | 0.825 | 1.375 | — |
| Example | | | | | |
| Comparative | 46.7 | 2.40 | 1.475 | 0.925 | — |
| Example | | | | | |
| Comparative | 46.7 | 2.40 | 0.925 | 1.475 | — |
| Example | | | | | |
| Conparative | 46.5 | 2.50 | 1.525 | 0.975 | — |
| Example | | | | | |
| Comparative | 46.5 | 2.50 | 0.975 | 1.525 | — |
| Example | | | | | |
| Comparative | 44.3 | 3.00 | 1.800 | 1.200 | — |
| Example | | | | | |
| Comparative | 44.3 | 3.00 | 1.200 | 1.800 | — |
| Example | | | | | |
| Comparative | 40.1 | 3.50 | 2.025 | 1.475 | — |
| Example | | | | | |
| Comparative | 40.1 | 3.50 | 1.475 | 2.025 | — |
| Example | | | | | |

TABLE 6
1000 Suns Concentration

| | | | Δ E_{ci1} | | Δ Eᵥᵢ₂ |
|---|---|---|---|---|---|
| | Efficiency | E_{g} | (Δ Eᵥᵢ₂) | Δ Eᵢᵢ₁₂ | (Δ E_{ci1}) |
| 4- levels | 44.1 | 1.00 | 0.650 | 0.250 | 0.100 |
| 4- levels | 44.1 | 1.00 | 0.350 | 0.550 | 0.100 |
| 4- levels | 49.9 | 1.20 | 0.750 | 0.275 | 0.175 |
| 4- levels | 49.9 | 1.20 | 0.450 | 0.575 | 0.175 |
| 4- levels | 58.4 | 1.60 | 0.950 | 0.325 | 0.325 |
| 4- levels | 58.4 | 1.60 | 0.650 | 0.625 | 0.325 |
| 4- levels | 62.8 | 2.00 | 1.150 | 0.350 | 0.500 |
| 4- levels | 62.8 | 2.00 | 0.850 | 0.650 | 0.500 |
| 4- levels | 63.7 | 2.20 | 1.250 | 0.350 | 0.600 |
| 4- levels | 63.7 | 2.20 | 0.950 | 0.650 | 0.600 |
| 4- levels | 63.8 | 2.30 | 1.300 | 0.350 | 0.650 |
| 4- levels | 63.8 | 2.30 | 1.000 | 0.650 | 0.650 |
| 4- levels | 63.4 | 2.50 | 1.400 | 0.350 | 0.750 |
| 4- levels | 63.4 | 2.50 | 1.100 | 0.650 | 0.750 |
| 4- levels | 59.8 | 3.00 | 1.650 | 0.375 | 0.975 |
| 4- levels | 59.8 | 3.00 | 1.350 | 0.675 | 0.975 |
| 4- levels | 57.5 | 3.20 | 1.750 | 0.350 | 1.100 |
| 4- levels | 57.5 | 3.20 | 1.450 | 0.650 | 1.100 |
| | Efficiency | E_{g} | Δ E_{ci1} | Δ Eᵥᵢ₁ | — |
| Comparative | 43.6 | 1.00 | 0.700 | 0.300 | — |
| Example | | | | | |
| Comparative | 43.6 | 1.00 | 0.300 | 0.700 | — |
| Example | | | | | |
| Comparative | 48.7 | 1.20 | 0.825 | 0.375 | — |
| Example | | | | | |
| Comparative | 48.7 | 1.20 | 0.375 | 0.825 | — |
| Example | | | | | |
| Comparative | 55.0 | 1.60 | 1.050 | 0.550 | — |
| Example | | | | | |
| Comparative | 55.0 | 1.60 | 0.550 | 1.050 | — |
| Example | | | | | |
| Comparative | 57.2 | 2.00 | 1.275 | 0.725 | — |
| Example | | | | | |
| Comparative | 57.2 | 2.00 | 0.725 | 1.275 | — |
| Example | | | | | |
| Comparative | 57.3 | 2.10 | 1.325 | 0.775 | — |
| Example | | | | | |
| Comparative | 57.3 | 2.10 | 0.775 | 1.325 | — |
| Example | | | | | |
| Comparative | 57.1 | 2.20 | 1.375 | 0.825 | — |
| Example | | | | | |
| Comparative | 57.1 | 2.20 | 0.825 | 1.375 | — |
| Example | | | | | |
| Comparative | 55.7 | 2.50 | 1.525 | 0.975 | — |
| Example | | | | | |
| Comparative | 55.7 | 2.50 | 0.975 | 1.525 | — |
| Example | | | | | |
| Comparative | 51.2 | 3.00 | 1.800 | 1.200 | — |
| Example | | | | | |
| Comparative | 51.2 | 3.00 | 1.200 | 1.800 | — |
| Example | | | | | |
| Comparative | 48.9 | 3.20 | 1.900 | 1.300 | — |
| Example | | | | | |
| Comparative | 48.9 | 3.20 | 1.300 | 1.900 | — |
| Example | | | | | |

With reference tables 5 and 6, when the comparison is made in the case of same E_{g}, the optimum band lineup of the 4-levels intermediate-band solar cell that exceeds the conversion efficiency of the intermediate-band solar cell in the comparative example is such that ΔE_{ci1}≧0.1 eV or ΔEᵥᵢ₂≧0.1 eV. The optimum band lineup is such that |(ΔE_{ci1}−ΔEᵥᵢ₂)|≧0.25 eV. Further, the optimum band lineup is such that ΔEᵢᵢ₁₂≧0.25 eV.

With reference to tables 5 and 6, in comparison with the maximum conversion efficiency of the intermediate-band solar cell in the comparative example, the optimum band lineup of the 4-levels intermediate-band solar cell that exceeds the maximum conversion efficiency of the intermediate-band solar cell in the comparative example is such that ΔE_{ci1}≧0.325 eV or ΔEᵥᵢ₂≧0.325 eV. The optimum band lineup is such that |(ΔE_{ci1}−ΔEᵥᵢ₂)|≧0.325 eV. Further, the optimum band lineup is such that ΔEᵢᵢ₁₂≧0.325 eV.

For example, when the 4-levels intermediate-band solar cell is composed of the quantum dots and the band offset between the quantum dots and the barrier layer in the valence band is 0 or the quantum level formed in the valence band can be regarded as one band (namely, when the two intermediate band levels are formed by using a potential formed due to the conduction band offset), as ΔEᵥᵢ₂ is larger (as ΔE_{ci1}+ΔEᵢᵢ₁₂ is smaller), the energy level Eᵢ₂ of the lowest intermediate band is closer to the bottom of the conduction band in the barrier layer, and the wave function of the electrons of the quantum dot layer easily interacts with the wave function of the adjacent quantum dot layer greatly. Therefore, the intermediate bands Eᵢ₁ and Eᵢ₂ are easily formed, and the carriers transfer more easily. When tables 5 and 6 are reviewed from such a viewpoint, the optimum band lineup of the 4-levels intermediate-band solar cell is preferably such that ΔEᵥᵢ₂≧(E_{g}/2+0.125) eV.

For example, when E_{g}=2.3 eV in the 4-levels intermediate-band solar cell in the case of thousandfold condensing, the band lineup that provides the energy conversion efficiency of 63.8%, namely, the combination of ΔE_{ci1} and ΔEᵥᵢ₂ is such that (ΔE_{ci1}, ΔEᵥᵢ₂)=(1.30 eV, 0.65 eV) (0.65 eV, 1.30 eV), (1.00 eV, 0.65 eV), and (0.65 ev, 1.00 eV). A preferable combination that satisfies the above band lineup is (ΔE_{ci1}, ΔEᵥᵢ₂)=(0.65 eV, 1.30 eV) based on the above condition that ΔEᵥᵢ₂≧(E_{g}/2+0.125) eV.

According to the experiment, the energy conversion efficiency is high in the 6-levels intermediate-band solar cell, the 5-levels intermediate-band solar cell, and the 4-levels intermediate-band solar cell.

The energy levels other than E_{g} in tables 1 to 6 are just some examples of E_{g}. That is to say, as to the energy levels other than E_{g} that satisfies the same efficiency for certain E_{g}, another combination can be considered based on a symmetric property of an energy interval. Further, tables 1 to 6 show just the optimum combinations of the energy levels that provide the maximum energy conversion efficiency to certain E_{g}, and the other combinations might exceed the energy conversion efficiency of the intermediate-band solar cell in the comparative example. Therefore, a technical range of the present invention is not limited to these examples.

### Simulation Experiment 2

A simulation experiment is further conducted on the superlattice semiconductor layer, which has the energy levels and is included in the solar cell (the 4 to 6-levels intermediate-band solar cell: referred also as a multi-level intermediate-band solar cell) shown in the experiments 1 to 3, with an attention being paid to a specific structure.

The Schrodinger equation is solved by using MATLAB software, and a band structure is calculated. In this simulation experiment, as a structure that can realize the multi-level intermediate-band solar cell, an attention is paid to “a structure where the valence band offset is 0” and “a structure where the valence band offset is not 0”. A shape of the quantum dot is considered as a cube, and a size of three sides are (x nm, y nm, z nm).

### [Experiment 4]

A band structure is calculated in the intermediate-band solar cell having a structure where the valence band offset is 0.

In the superlattice semiconductor layer having the superlattice structure where the barrier layers made of AlSb and the quantum dot layers made of the quantum dots of InAs₁₋ₓSbₓ are stacked repeatedly, a difference between the energy level at the top of the valence band in the barrier layer and the energy level at the top of the valence band in the material (bulk) composing the quantum dots can be set to 0, and the valence band offset can be 0 (the valence band offset is such that a difference in the energy level of the top of the valence band between InAsₓSb₁₋ₓ and AlSb is 0). Since the electrons of InAs₁₋ₓSbₓ are quantum confined in AlSb at a point Γ, the band structures of InAs₁₋ₓSbₓ and AlSb at the point Γ are considered. The following calculation is made under a condition that x=0.3 according to the Vegard's law. The band gap of AlSb at the point Γ is 2.3 eV, and the band gap of InAs_{0.7}Sb_{0.3} at the point Γ is 0.3 eV. Further, the conduction band offset is 2.0 eV, and the valence band offset is 0.0 eV.

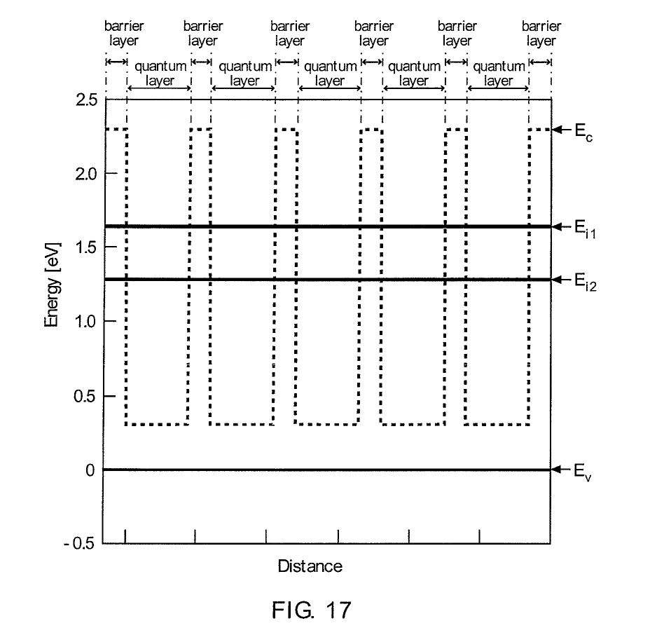

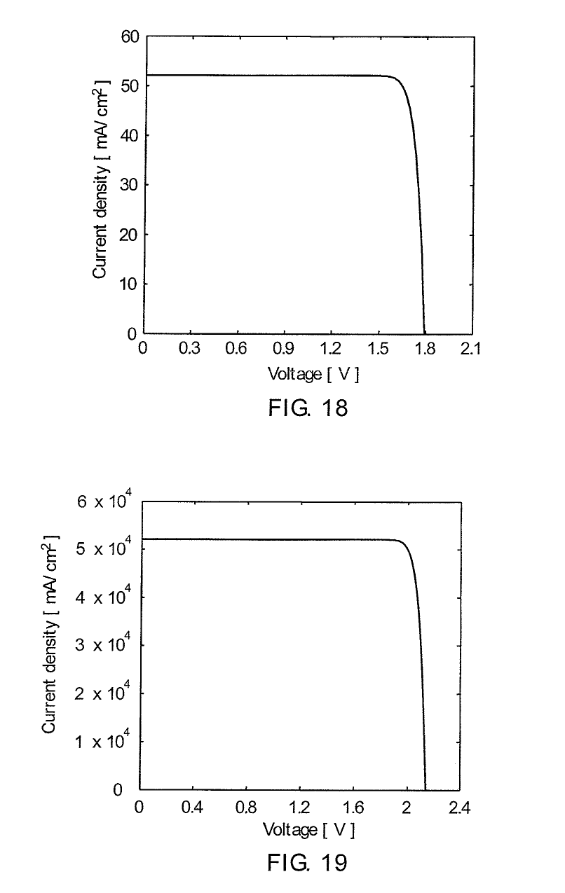

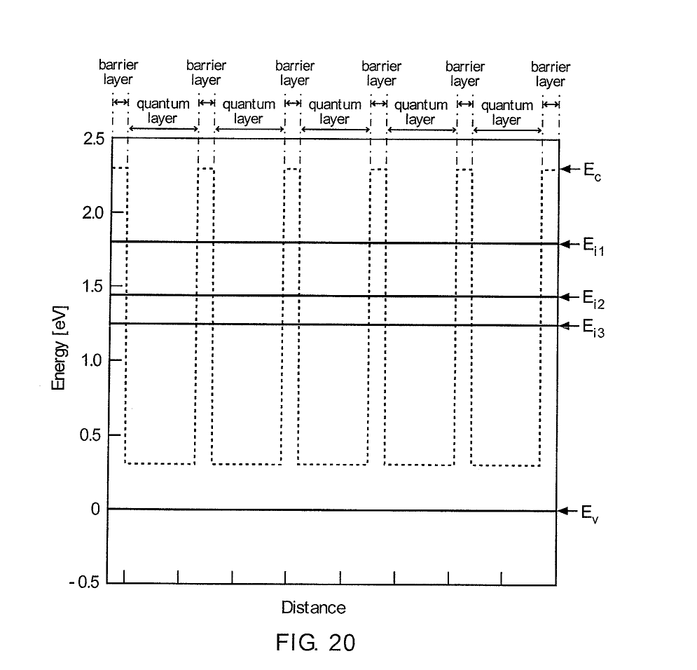

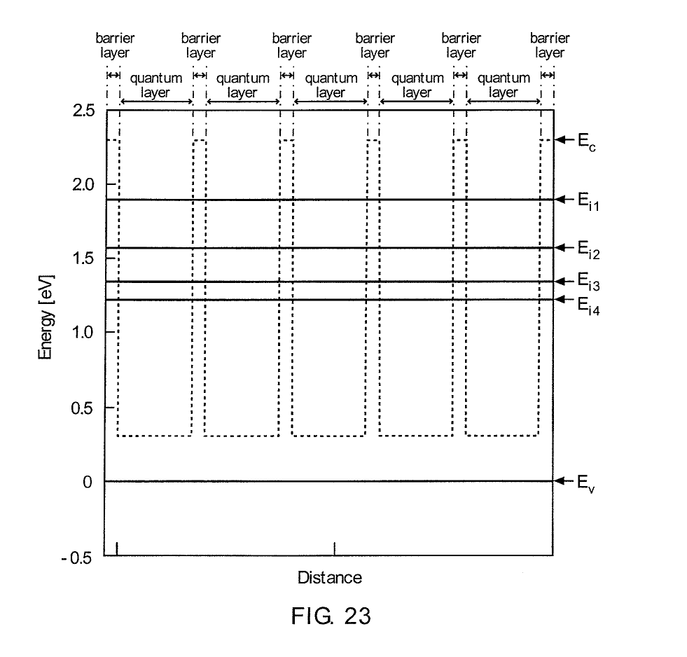

Results of calculating the band structures where the valence band offset is 0 are shown in FIGS. 17 to 25. FIGS. 17, 20 and 23 are diagrams showing the results of calculating the band structures of the intermediate-band solar cells. As to the multi-level intermediate-band solar cell in these drawings, the 4-levels intermediate-band solar cell is shown in FIG. 17, the 5-levels intermediate-band solar cell is shown in FIG. 20, and the 6-levels intermediate-band solar cell is shown in FIG. 23. In the solar cells in these drawings, the valence band offset between the quantum dot layers and the barrier layers is 0, and the quantum dot layers is made of InAs_{0.7}Sb_{0.3} and the barrier layers is made of AlSb. Further, FIGS. 18, 19, 21, 22, 24 and 25 are diagrams showing results of simulating a relationship between a voltage and an electric current when light is irradiated to the solar cells in FIGS. 17, 20 and 23.

### [Experiment 4-1]

The band structure of the 4-levels intermediate-band solar cell where the valence band offset is 0 is calculated.

In this experiment, the calculation is made on the superlattice structure where the barrier layers made of AlSb having a thickness of 2 nm, and the quantum dot layers made of InAs_{0.7}Sb_{0.3} having the quantum dots with a size of (2.7 nm, 2.7 nm, 9 nm) are repeatedly stacked.

In FIG. 17 showing the calculated result, a horizontal axis represents a distance of the superlattice semiconductor layer in a thickness-wise direction (a direction z in FIG. 1), and a vertical axis represents the energy. A doted line shown in FIG. 17 indicates the energy levels at the bottoms E_{c} of the conduction bands in the barrier layers and the quantum dot layers (bulk state). In this experiment, since the band offset is 0, the energy levels Eᵥ at the tops of the valence bands in the barrier layers and the quantum dot layers are the same. Further, FIG. 17 shows the energy levels Eᵢ₁ and Eᵢ₂ of the intermediate band formed by the quantum levels of the quantum dot layers and calculated by the simulation.

FIGS. 20 and 23 are diagrams drawn by the similar method.

As a result of the simulation, as shown in FIG. 17, in a case of such a quantum dot size, when the energy level at the top of the valence band is 0, the respective energy levels are such that (Eᵥ, Eᵢ₂, Eᵢ₁, E_{c})=(0, 1.29, 1.64, 2.32) eV due to confining from three directions.

FIGS. 18 and 19 are diagrams showing results of simulating the relationship between the voltage and the electric current when no concentration light (FIG. 18) or 1000 suns concentration light (FIG. 19) is irradiated to the 4-levels intermediate-band solar cell by using these energy levels.

The energy conversion efficiency of the 4-levels intermediate-band solar cell that was calculated by using these energy levels was 51.9% in the case of non-condensing and was 63.4% in the case of thousand-fold condensing.

### [Experiment 4-2]

The band structure of the 5-levels intermediate-band solar cell where the valence band offset is 0 was calculated.

In this experiment, a calculation was made on the superlattice structure where the barrier layers made of AlSb having a thickness of 2 nm and the quantum dot layers made of InAs_{0.7}Sb_{0.3} and the quantum dots with a size of (2.7 nm, 2.7 nm, 13 nm) are stacked repeatedly.

The calculated result is shown in FIG. 20. As shown in FIG. 20, in a case of such a quantum dot size, when the top of the valence band was 0, the respective energy levels were such that (Eᵥ, Eᵢ₃, Eᵢ₂, Eᵢ₁, E_{c})=(0, 1.25, 1.44, 1.80, 2.3) eV due to confining from three directions.

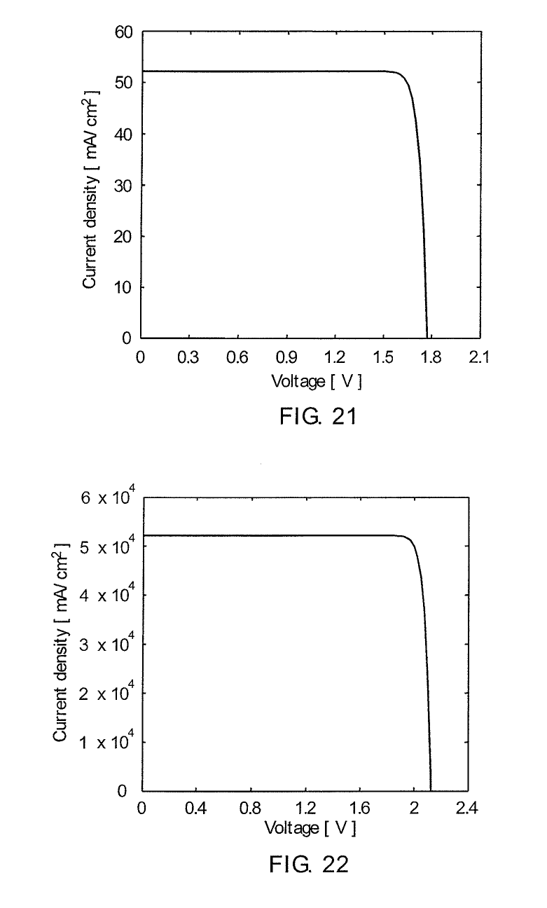

FIGS. 21 and 22 are diagrams showing results of simulating a relationship between the voltage and the electric current when no concentration light (FIG. 18) or 1000 suns concentration light (FIG. 19) is irradiated to the 5-levels intermediate-band solar cell by using these energy levels.

The energy conversion efficiency of the 5-levels intermediate-band solar cell that was calculated by using these energy levels was 52.1% in the case of non-condensing and 63.6% in the case of thousandfold condensing.

### [Experiment 4-3]

The band structure of the 6-levels intermediate-band solar cell where the valence band offset was 0 was calculated.

In this experiment, the calculation was made on the superlattice structure where the barrier layers made of AlSb having a thickness of 2 nm and the quantum dot layers made of InAs_{0.7}Sb_{0.3} and the quantum dots having a size of (2.7 nm, 2.7 nm, 17 nm) were repeatedly stacked.

The calculated result is shown in FIG. 23. As shown in FIG. 23, in a case of such a quantum dot size, when the top of the valence band was 0, the respective energy levels were such that (Eᵥ, Eᵢ₄, Eᵢ₃, Eᵢ₂, Eᵢ₁, E_{c})=(0, 1.23, 1.35, 1.57, 1.90, 2.3) eV due to confining from three directions.

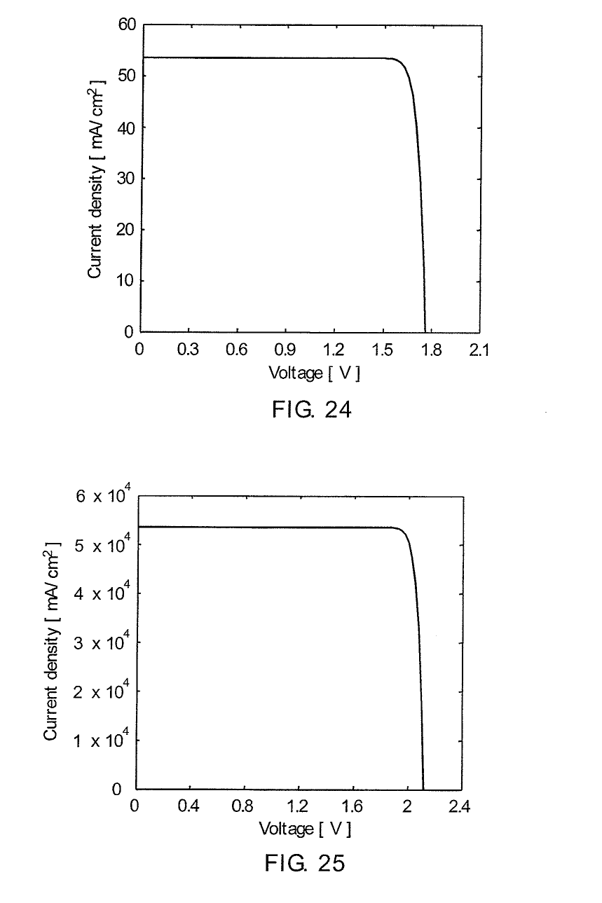

FIGS. 24 and 25 are diagrams showing results of simulating the relationship between the voltage and the electric current when no concentration light (FIG. 24) or 1000 suns concentration light (FIG. 25) is irradiated to the 6-levels intermediate-band solar cell by using these energy levels.

The energy conversion efficiency of the 6-levels intermediate-band solar cell that was calculated by using the energy levels was 53.2% in the case of non-condensing and was 65.0% in the case of thousandfold condensing.

### [Experiment 5]

The band structure of the intermediate-band solar cell where the valence band offset was not 0 was calculated.

Heavy holes and light holes are present in the valence band of a semiconductor. Since an effective mass of the heavy hole is comparatively large, when the valence band offset is comparatively small, a lot of quantum energy levels are formed in the valence band of the quantum dots (the quantum dot layer), and the plurality of levels can be regarded as one valence band. The interval between the top of the valence band, which is regarded as one, and the bottom of the conduction band of the barrier layer can be considered as an effective band gap, and thus the multi-level intermediate-band solar cell can be realized. As such a combination, a combination of the barrier layer made of AlSb₁₋ₓAsₓ and the quantum dot layer made of InAs is present.

On the other hand, in this combination, since InAs is quantum confined in AlSb₁₋ₓAsₓ at the point Γ similarly to the above case, the band structures of InAs and AlSb₁₋ₓAsₓ at the point Γ are considered. The following calculation was made when x=0.5 according to Vegard's law. The band gap of InAs at the point Γ is 0.35 eV, and the band gap of AlSb_{0.5}As_{0.5} at the point Γ is 2.65 eV. Further, the conduction band offset is 2.02 eV, and the valence band offset is 0.28 eV.

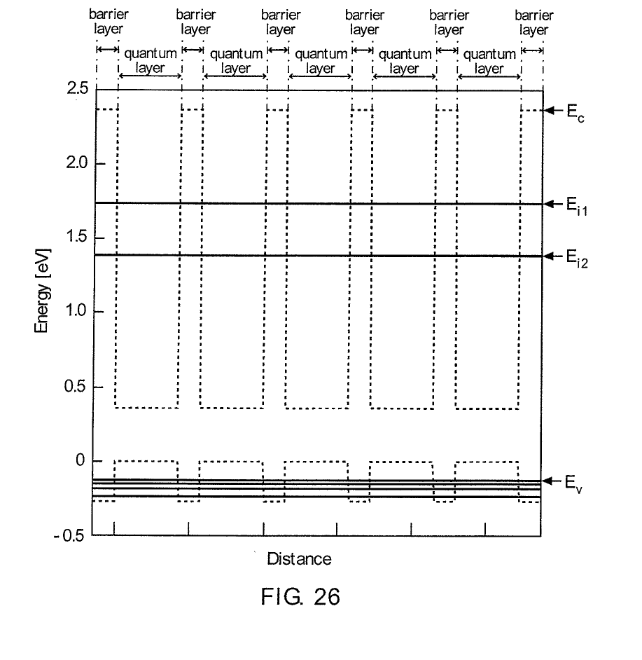

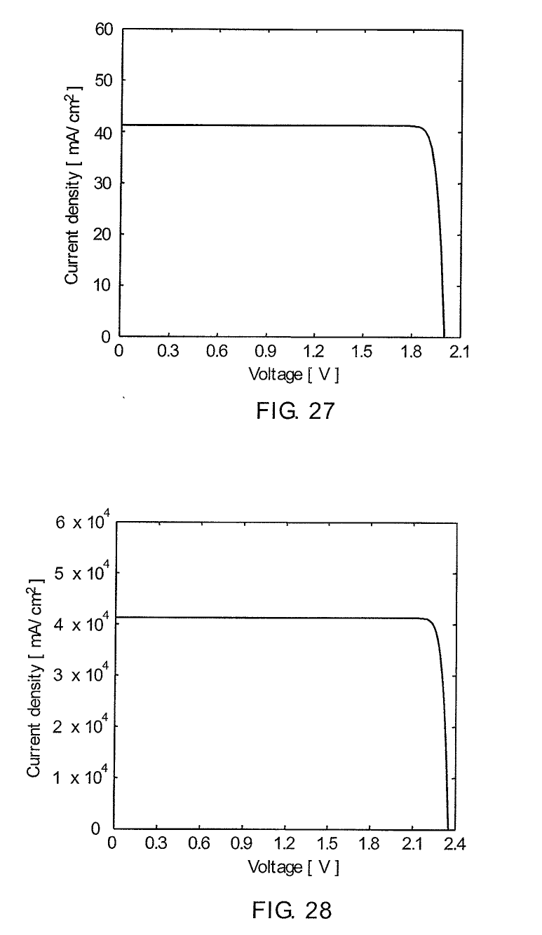

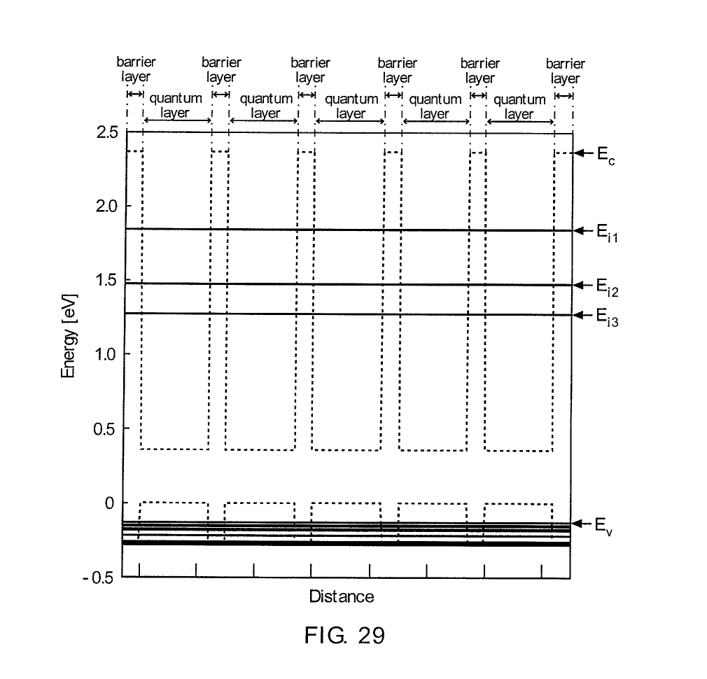

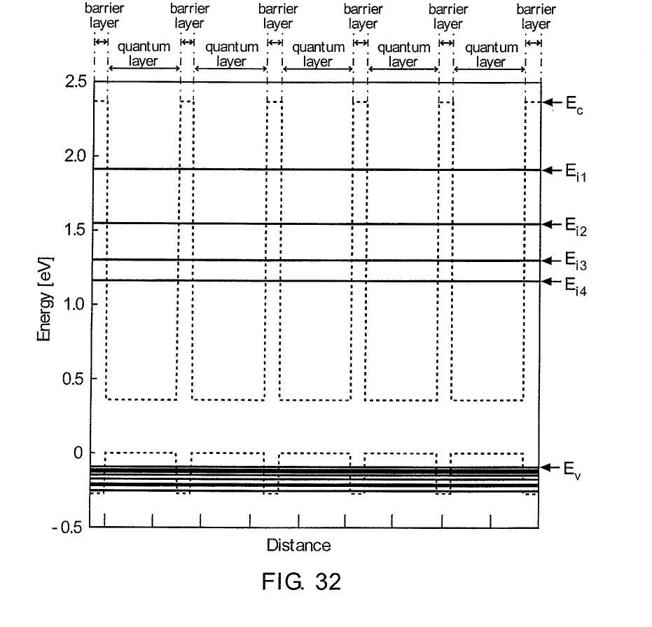

Results of calculating the band structure where the valence band offset is not 0 are shown in FIGS. 26 to 34. FIGS. 26, 29 and 32 are diagrams showing the results of calculating the band structure of the intermediate-band solar cell. As to the intermediate-band solar cells in these drawings, the 4-levels intermediate-band solar cell is shown in FIG. 26, the 5-levels intermediate-band solar cell is shown in FIG. 29, and the 6-levels intermediate-band solar cell is shown in FIG. 32. Further, in the solar cells in these drawings, the valence band offset between the quantum dot layers and the barrier layers is not 0, and the quantum dot layers are made of InAs and the barrier layers are made of AlSb_{0.5}As_{0.5}. FIGS. 27 and 28, FIGS. 30 and 31, and FIGS. 33 and 34 are diagrams showing results of simulating the relationship between the voltage and the electric current when light is irradiated to the solar cell in FIGS. 26, 29 and 32.

### [Experiment 5-1]

The band structure of the 4-levels intermediate-band solar cell where the valence band offset was not 0 was calculated.

In this experiment, the calculation was made on the superlattice structure where the barrier layers made of AlSb_{0.5}As_{0.5} having a thickness of 2 nm and the quantum dot layers made of InAs and the quantum dots having a size (2.5 nm, 2.5 nm, 8.5 nm) were repeatedly stacked.

In FIG. 26 showing the calculated result, a horizontal axis represents a distance of the superlattice semiconductor layer in a thickness-wise direction (the direction z in FIG. 1), and a vertical axis represents the energy. Further, one of two dotted lines shown in FIG. 26 represents the energy level at the bottoms E_{c} of the conduction bands in the barrier layer and the quantum dot layer (bulk state), and the other one represents the energy level at the tops of the valence bands in the barrier layer and the quantum dot layer (bulk state). Further, FIG. 26 shows the energy levels Eᵢ₁ and Eᵢ₂ of the intermediate band that are formed by the quantum levels of the quantum dot layers and are calculated by the simulation, and a miniband formed by the quantum levels on the valence band side in the quantum dot layers. According to an experiment 6, described later, the quantum levels on the valence band side form the miniband.

FIGS. 29 and 32 are drawn by the similar method.

As shown in FIG. 26, a plurality of minibands that is formed by the quantum levels on the valence band side of the quantum dot layers is formed in a narrow energy range. For this reason, the plurality of minibands can be substantially regarded as one valence band.

As shown in FIG. 26, in a case of such quantum dot sizes, when an energy level Eᵥ at the top of the valence band substantially regarded as one band is 0, the respective energy levels are such that (Eᵥ, Eᵢ₂, Eᵢ₁, E_{c})=(0, 1.54, 1.90, 2.52) eV due to confining from 3 directions. These four values are different from those which are drawn at the side of the vertical axis of FIG. 26. This is only due to the difference of the basing point. Eᵥ is the energy level at the top of the valence band regarded as one band, and E_{c} is the energy level at the bottom of a conductor in the barrier layer. Therefore, (E_{c}−Eᵥ) is not the band gap of the barrier layer, and is the effective bandgap.

FIGS. 27 and 28 are diagrams showing results of simulating the relationship between the voltage and the electric current when no concentration light (FIG. 27) or thousandfold light (FIG. 28) is irradiated to the 4-levels intermediate-band solar cell by using these energy levels.

The energy conversion efficiency of the 4-levels intermediate-band solar cell that was calculated by using these energy levels were 47.7% in the case of non-condensing, and 56.8% in the case of thousandfold condensing.

### [Experiment 5-2]

The band structure of the 5-levels intermediate-band solar cell where the valence band offset was not 0 was calculated.

In this experiment, the calculation was made on the superlattice structure where the barrier layers made of AlSb_{0.5}As_{0.5} having a thickness of 2 nm, and the quantum dot layers made of InAs and the quantum dots having a size of (2.7 nm, 2.7 nm, 12 nm) were repeatedly stacked.

The calculated result is shown in FIG. 29. As shown in FIG. 29, a plurality of minibands formed by the quantum levels on the valence band side of the quantum dot layers is formed in a narrow energy range. For this reason, the plurality of minibands can be substantially regarded as one valence band. According to experiments 6 and 7, described later, it is considered that the quantum levels on the valence band side form the minibands.

As shown in FIG. 29, in the case of such a quantum dot size, when the energy level Eᵥ at the top of the valence band substantially regarded as one band is 0, the respective energy levels are such that (Eᵥ, Eᵢ₃, Eᵢ₂, Eᵢ₁, E_{c})=(0, 1.41, 1.61, 1.98, 2.50) eV due to confining from three directions. These five values are different from those which are drawn at the side of the vertical axis of FIG. 29. This is only due to the difference of the basing point. Eᵥ is the energy level at the top of the valence band regarded as one band, and E_{c} is the energy level at the bottom of the conductor in the barrier layer. Therefore, (E_{c}−Eᵥ) is not the band gap of the barrier layer, and is the effective bandgap.

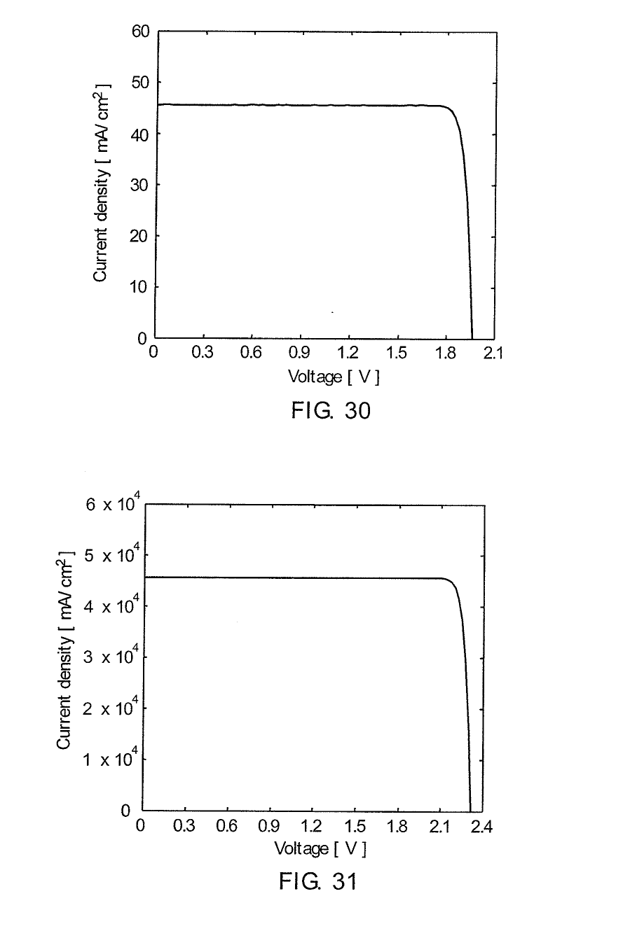

FIGS. 30 and 31 are diagrams showing results of simulating the relationship between the voltage and the electric current when no concentration light (FIG. 30) or 1000 suns concentration light (FIG. 31) is irradiated to the 5-levels intermediate-band solar cell by using these energy levels.

The energy conversion efficiency of the 5-levels intermediate-band solar cell that was calculated by using these energy levels was 51.3% in the case of non-condensing, and 61.4% in the case of thousandfold condensing.

### [Experiment 5-3]

The band structure of the 6-levels intermediate-band solar cell where the valence band offset is not 0 was calculated.

In this experiment, the calculation was made on the superlattice structure where the barrier layers made of AlSb_{0.5}As_{0.5} having a thickness of 2 nm and the quantum dot layers made of InAs and the quantum dots having a size (3.0 nm, 3.0 nm, 15 nm) were repeatedly stacked.

The calculated result is shown in FIG. 32. As shown in FIG. 32, a plurality of minibands formed by the quantum levels on the valence band side of the quantum dot layers is formed in a narrow energy range. For this reason, the plurality of minibands can be substantially regarded as one valence band. According to an experiment 7, described later, the quantum levels on the valence band side form the minibands.

As shown in FIG. 32, in a case of such a quantum dot size, when the energy level Eᵥ at the top of the valence band substantially regarded as one band was 0, the respective energy levels were such that (Eᵥ, Eᵢ₄, Eᵢ₃, Eᵢ₂, Eᵢ₁, E_{c})=(0, 1.28, 1.42, 1.67, 2.03, 2.49) eV due to confining from 3 directions. These six values are different from those which are drawn at the side of the vertical axis of FIG. 32. This is only due to the difference of the basing point. Eᵥ is the energy level at the top of the valence band regarded as one band, and E_{c} is the energy level at the bottom of the conductor of the barrier layer. Therefore, (E_{c}−Eᵥ) is not the band gap of the barrier layer, but is the effective bandgap.

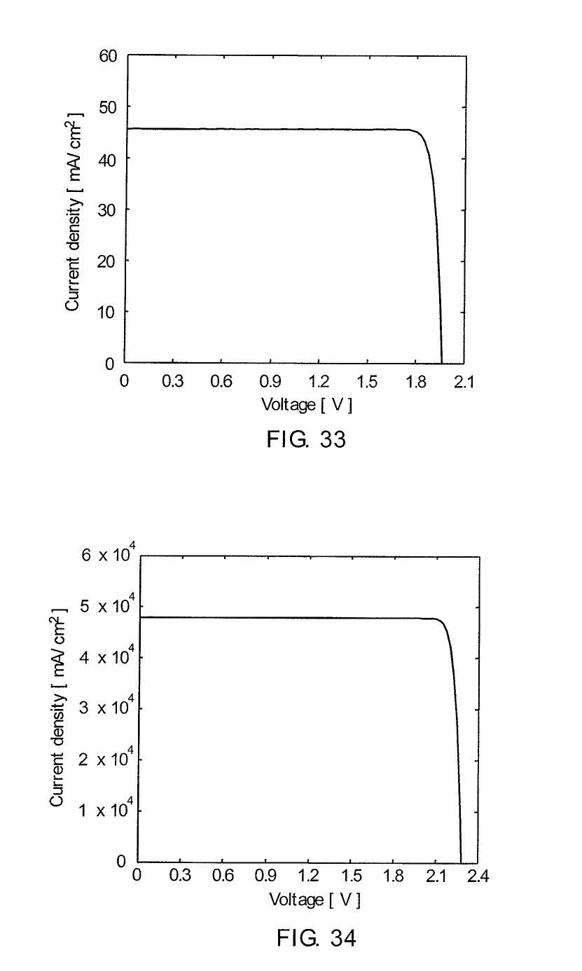

FIGS. 33 and 34 are drawings showing results of simulating the relationship between the voltage and the electric current when no concentration light (FIG. 33) or 1000 suns concentration light (FIG. 34) is irradiated to the 6-levels intermediate-band solar cell by using the energy levels.

The energy conversion efficiency of the 6-levels intermediate-band solar cell that was calculated by using these energy levels was 52.8% in the case of non-condensing and 63.4% in the case of thousandfold condensing.

According to the results of the experiments 4 and 5, it is understood that when the valence band offset is 0 or is not 0, the 4 to 6-levels intermediate-band solar cells produce high energy efficiency.

### With Regard to the Barrier Layer and the Quantum Layer

The experiments 4 and 5 exemplified the superlattice structure where the barrier layers made of AlSb and the quantum dot layers made of InAs_{0.7}Sb_{0.3} are stacked, and the superlattice structure where the barrier layers made of AlSb_{0.5}As_{0.5} and the quantum dot layers made of InAs are stacked. However, the barrier layers and the quantum layers included in the solar cell of the this application are not limited to them. For example, the superlattice structure may be such that the barrier layers made of AlSb_{y}As_{1-y} (0≦y≦1) and the quantum layers made of InSbₓAs₁₋ₓ (0≦x≦1) are stacked and the mixed crystal ratio between x and y obtains any value.

In the barrier layers and the quantum layers included in the solar cell of this application, as materials having close lattice constants and similar crystal structures, InAs, GaAs, AlAs, InSb, GaSb, AlSb, InP, GaP and AlP described in Table 7 may be used (the energy values of the conduction band and the valence band in Table 7 are based on the valence band of InSb). That is to say, similarly to the experiments 4 and 5, in order to obtain high energy conversion efficiency, a group III-V compound semiconductor having at least one element of (Al, Ga, In) and at least one element of (As, Sb, P) can be used as the barrier layer or the quantum layer.

TABLE 7

| | Band Gap | Conduction | Valance | Lattice |
|---|---|---|---|---|
| | (Γ point) | Band | Band | Constant |
| Semiconductor | [eV] | [eV] | [eV] | [Å] |
| InAs | 0.354 | −0.236 | −0.590 | 6.058 |
| AlSb | 2.300 | 1.890 | −0.410 | 6.136 |
| GaSb | 0.725 | 0.695 | −0.030 | 6.096 |
| InSb | 0.170 | 0.170 | 0.000 | 6.479 |
| AlAs | 3.000 | 1.670 | −1.330 | 5.661 |
| GaAs | 1.424 | 0.624 | −0.800 | 5.653 |
| InP | 1.350 | 0.410 | −0.940 | 5.870 |
| GaP | 2.780 | 1.510 | −1.270 | 5.451 |
| AlP | 3.600 | 1.860 | −1.740 | 5.467 |

The quantum level can be changed by changing the materials, the mixed crystal ratio, the quantum dot size and the thickness of the barrier layer. However, the smaller the band gap is, the more easily the intermediate band is formed on a desired position, thereby improving a degree of freedom of the energy level formation. Therefore, it is more preferable that InAs, InSb or a mixed crystal material of them is used as the quantum dot layer, and AlSb, GaSb, InP, AlAs, GaAs, AlP, GaP or a mixed crystal material of them is used as the barrier layer.

A chalcopyrite-type material or a II-VI compound semiconductor can be also used as the barrier layer or the quantum layer. For example, CuInSe₂ has a band gap of 1.04 eV, CuAlSe₂ has a band gap of 2.67 eV, and their valence band offset is 0.26 eV, which is a small value. Further, CuGaSe₂ has a band gap of 1.68 eV, the valence band offset between CuGaSe₂ and CuInSe₂ is 0.04 eV, which is a very small value, and thus valence band offset is close to 0.

The materials of the barrier layer and the p-type and n-type semiconductor layers are preferably the same as each other from a viewpoint of production, but the materials may be different from each other.

### With Regard to Quantum Level on the Valence Band Side of the Quantum Layer

Since heavy holes whose effective mass is large are present in the valence band, a lot of quantum energy levels on the valence band side of the quantum layer are easily formed more densely (intervals of the quantum energy levels are small), and can be substantially regarded as one valence band. As a result, in the valence band substantially regarded as one band, the holes easily transfers and are easily taken out to the p-type semiconductor layer. For example, some energy levels are shown in the valence band regions in FIGS. 26, 29 and 32, and are sufficiently dense. Therefore, even when the valence band offset is not 0, the dense quantum energy levels can be substantially regarded as one valence band.

It is preferable that the valence band offset is comparatively small, because the wave functions between the adjacent quantum dots are easily coupled electronically, and the minibands are formed so that the holes easily transfer.

### Simulation Experiment 3

A simulation experiment was conducted to calculate the superlattice structure as the band structure of the intermediate-band solar cell where the valence band offset was not 0 by using a Kronig-Penney model. In this experiment, the superlattice structure where the barrier layers made of AlSb_{0.5}As_{0.5} and the quantum dot layers made of InAs were repeatedly stacked was calculated. In the combination of the barrier layer and the quantum dot layer, as described in the experiment 5, the valence band offset is 0.28 eV, and the conduction band offset is 2.02 eV.

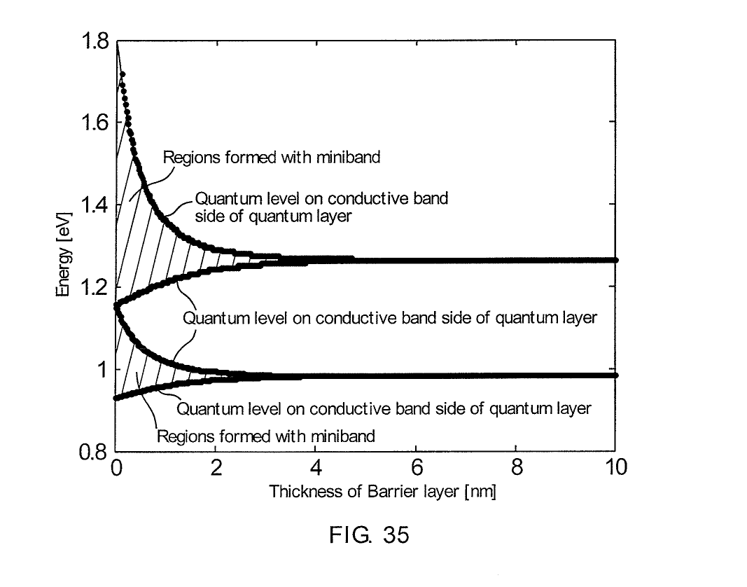

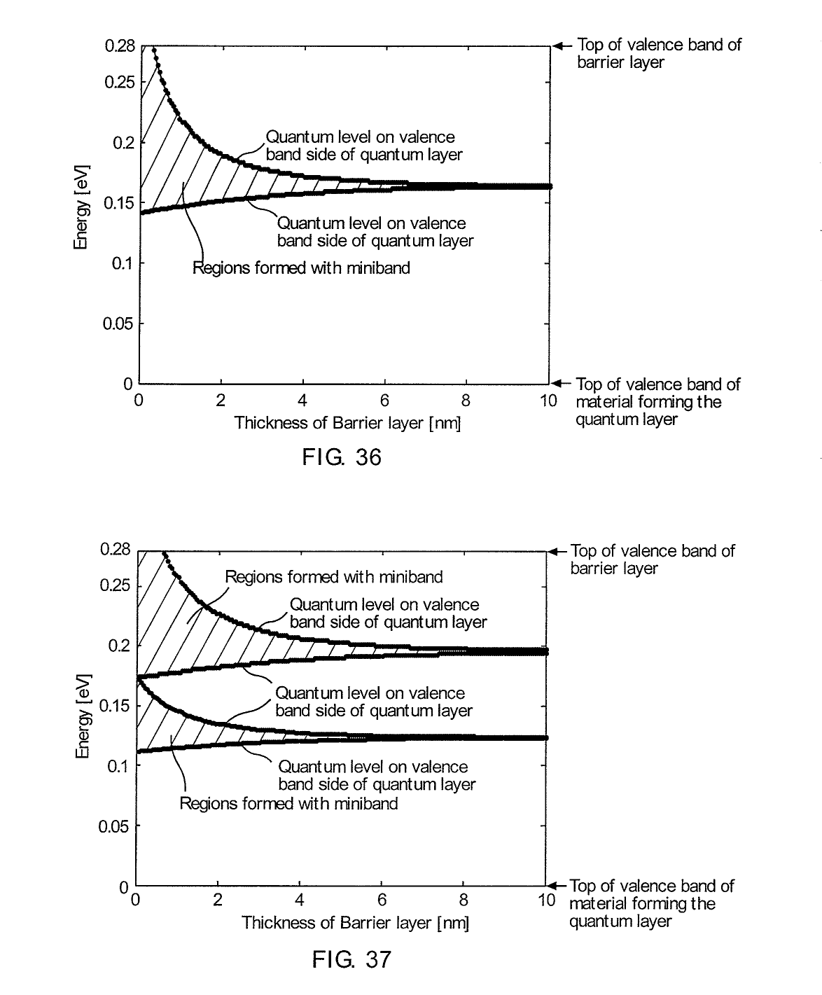

The result of calculating the quantum level on the conduction band side of the quantum dot layer is shown in FIG. 35, and the results of calculating the quantum level on the valence band side are shown in FIGS. 36 and 37. Horizontal axes in FIGS. 35 to 37 represent the thickness of the barrier layer sandwiched between the quantum dot layers, and vertical axes represent the energy.

In FIGS. 36 and 37, 0 eV in the vertical axes is the energy level at the top of the valence band of the material (bulk) forming the quantum dot layer, and 0.28 eV is the energy level at the top of the valence band of the barrier layer (namely, a difference between a lower side and an upper side in the graphs of FIGS. 36 and 37 becomes the valence band offset). FIG. 35 shows the quantum level on the conduction band side of the quantum dot layer, and FIGS. 36 and 37 show the quantum level on the valence band side of the quantum dot layer. Regions indicated by slanted lines in FIGS. 35 to 37 are regions where minibands are formed at the respective thickness of the barrier layers.

FIGS. 36 and 37 show the energy level based on the energy of the holes. It is stable that the holes transfer to a lower energy, and the holes obtain the energy level in such a state. Further, it is stable that the electrons transfer to a higher energy, and the electrons obtain the energy level in such a state.

### [Experiment 6]

The band structure of the 4-levels intermediate-band solar cell where the valence band offset was not 0 was calculated. A result of calculating the quantum level on the conduction band side of the quantum dot layer is shown in FIG. 35, and a result of calculating the quantum level on the valence band side is shown in FIG. 36.

In this experiment, the calculation was made on the superlattice structure where the barrier layers made of AlSb_{0.5}As_{0.5} and the quantum dot layers made of InAs and the quantum dots having a size of (2.5 nm, 2.5 nm, 8.5 nm) were repeatedly stacked. It is considered that the contribution of the energy levels from two directions other than the direction z does not greatly depend on the barrier layer, and as to the quantum energy level in FIGS. 35 and 36, the energy levels from two directions other than the direction z are approximately added. The quantum energy level in FIG. 36 is some of energy levels of light holes.

With reference to FIG. 35 showing the result of calculating the quantum level on the conduction band side of the quantum dot layer, when the thickness of the barrier layer is 2 nm, the region indicated by the slanted lines has a finite width, and miniband is formed. Further, the miniband is formed to about 3 nm of the barrier layer.

According to this result, even when the conduction band offset is 2.02 eV, which is a large value, and the thickness of the barrier layer is about 3 nm, the miniband is formed. Therefore, the thickness of the barrier layer is preferably 3 nm or less.

With reference to FIG. 36 showing the result of calculating the quantum level on the valence band side of the quantum dot layer, when the thickness of the barrier layer is 2 nm, the region indicated by the slanted lines has a finite width, and miniband is formed. Further, the miniband is formed to about 6 to 7 nm of the barrier layer.

In the experiments 5-1 and 6, the size of the quantum dot in the direction z is set to 8.5 nm as one example, but it may be 2.5 nm, and in this case, it was confirmed that the miniband is formed.

When the size of quantum dot is set to 2.5 nm, the quantum level on the valence band side of the quantum dots is close to the energy level at the top of the valence band of the barrier layer, and the quantum level on the conduction band side of the quantum dots is close to the energy level at the bottom of the conduction band of the barrier layer, so that quantum confinement is weakened. For this reason, in a case of comparison of the same thickness of barrier layers, the miniband width becomes larger. The thickness of the barrier layer where the miniband can be formed becomes large.

### [Experiment 7]

The band structure of the 6-levels intermediate-band solar cell where the valence band offset was not 0 was calculated. The result of calculating the quantum level on the valence band side of the quantum dot layer is shown in FIG. 37.

In this experiment, the calculation was made on the superlattice structure where the barrier layers made of AlSb_{0.5}As_{0.5} and the quantum dot layers made of InAs and the quantum dots with a size of (3.0 nm, 3.0 nm, 15 nm) were repeatedly stacked. It is considered that contribution of the energy levels from two direction other than the direction z does not greatly depend on the barrier layer, and as to the quantum energy level in FIG. 37, the energy levels from the two directions other than the direction z are approximately added. The quantum energy levels in FIG. 37 are some of energy levels of light holes.

With reference to FIG. 37 showing the result of this experiment, when the thickness of the barrier layer is 2 nm, the region indicated by slanted lines has a finite width, and minibands are formed. Further, the miniband is formed to about 6 to 7 nm of the barrier layer.

In the experiments 5-3 and 7, the size of the quantum dots in the direction z is set to 15 nm as one example, but may be set to 3 nm, and in this case, the miniband is formed. When the size of the quantum dots is set to 3 nm, the quantum level on the valence band side of the quantum dots is close to the energy level at the top of the valence band of the barrier layer, and the quantum level on the conduction band side of the quantum dots is close to the energy level at the bottom of the conduction band of the barrier layer, so that the quantum confinement is weakened. For this reason, when the comparison is made by using the same thicknesses of the barrier layer, the miniband width becomes large. Further, the thickness of the barrier layer where the miniband can be formed becomes large.

According to the above result, when the valence band offset is 0.28 eV, the miniband is sufficiently formed, and from a viewpoint of the formation of the miniband, the smaller the valence band offset is, the more preferable. It is more preferable that the valence band offset is 0 like the experiment 4, and in this case, the holes might transfer very smoothly.

The experiment 5 used a type I material in which the top of the valence band of the quantum dot layer is higher than the top of the valence band of the barrier layer. However, a type II material in which the top of the valence band of the barrier layer is higher than the top of the valence band of the quantum dot layer may be used for the barrier layer and the quantum layer.

The above embodiments describes the present invention, but the present invention is not limited to these embodiments.

For example, a resonance tunnel effect between the quantum levels is produced due to electronic coupling of the wave functions between the quantum dots in the superlattice structure. It is preferable from a viewpoint of carrier transfer that the intermediate band obtained by connecting the quantum levels into one is formed, but the intermediate band is not necessarily formed. As described in Applied Physics Letters, Vol. 96, page 203507, 2010, the quantum energy levels formed by the respective quantum dots do not resonate and may be present independently, and even such a configuration functions as the intermediate-band solar cell. For this reason, the intermediate bands in the above embodiments (and the experiments 1 to 7) may have the energy levels that are present independently in the quantum layer.

The above embodiments (and the experiments 1 to 7) describes the superlattice structure that is mainly formed by the quantum dot layers, but for example, the present invention may be applied to the intermediate band formed in the superlattice structure formed by the quantum well layer. The present invention is not limited to the intermediate-band solar cell using the quantum dots.

The present invention can be variously modified within a scope described in the following claims. That is to say, an embodiment that is obtained by combining technical means suitably changed within the scope described in the claims is also included in the technical scope of the present invention.

What is claimed is:

1. A solar cell comprising a p-type semiconductor layer, an n-type semiconductor layer and a superlattice semiconductor layer sandwiched between the p-type semiconductor layer and the n-type semiconductor layer, wherein
the superlattice semiconductor layer has a superlattice structure in which barrier layers and quantum layers are stacked alternately and repeatedly, and has two or more intermediate energy levels where electrons optically excited from a valence band of the quantum layers or the barrier layers stay for a constant time, the intermediate energy levels being located between a top of the valence band of the barrier layers and a bottom of a conduction band of the barrier layers.

2. The solar cell according to claim 1, wherein
each of the intermediate energy levels is composed of quantum levels on a conduction band side of the quantum layers, and
an effective bandgap between a quantum level at a top of the valence band side of the quantum layers and the bottom of the conduction band of the barrier layers is 1.0 eV or more to 3.8 eV or less.

3. The solar cell according to claim 1, wherein the quantum layers are quantum dot layers, each of which is composed of quantum dots.

4. The solar cell according to claim 1, wherein the quantum layers or the barrier layers are made of a III-V compound semiconductor, a II-VI compound semiconductor or a chalcopyrite-type semiconductor.

5. The solar cell according to claim 1, wherein the quantum layers or the barrier layers are made of a III-V compound semiconductor including at least one element of Al, Ga and In, and at least one element of As, Sb and P.

6. The solar cell according to claim 1, wherein the quantum layers are made of InSbₓAs₁₋ₓ (0≦x≦1) and the barrier layers are made of AlSb_{y}As_{1-y} (0≦y≦1).

7. The solar cell according to claim 1, wherein the quantum layers have the valence band that can be substantially regarded as one band, the valence band being composed of a plurality of quantum levels on the valence band side of the quantum layers.

8. The solar cell according to claim 1, wherein a valence band offset as a difference between the top of the valence band of the barrier layers and a top of a valence band of a material forming the quantum layers, is 0.0 eV or more to 0.28 eV or less.

9. The solar cell according to claim 8, wherein the valence band offset is substantially 0 eV.

10. The solar cell according to claim 1, wherein the intermediate energy levels are intermediate bands, each of which comprises electronically combined wave functions of the quantum levels of the quantum layers composing the superlattice structure.

11. The solar cell according to claim 2, wherein the number of the intermediate energy levels is 2, and the effective bandgap is 1.0 eV or more to 3.5 eV or less.

12. The solar cell according to claim 2, wherein the number of the intermediate energy levels is 3, and the effective bandgap is 1.1 eV or more to 3.8 eV or less.

13. The solar cell according to claim 2, wherein the number of the intermediate energy levels is 4, and the effective bandgap is 1.3 eV or more to 3.8 eV or less.

14. The solar cell according to claim 1, wherein each of the barrier layers has a thickness of 3 nm or less.
